(19) United States
(12) Patent Application Publication
(10) Pub. No.: US 2013/0077065 A1
(43) Pub. Date: Mar. 28, 2013

(54) CLEANING SUBSTRATE FOR A LITHOGRAPHY APPARATUS, A CLEANING METHOD FOR A LITHOGRAPHY APPARATUS AND A LITHOGRAPHY APPARATUS

(71) Applicants: Raymond Wilhelmus Louis LAFARRE, Helmond (NL); Roelof Frederik De Graaf, Veldhoven (NL); Niek Jacobus Johannes Roset, Eindhoven (NL); Arjan Hubrecht Josef Anna Martens, Valkenburg (NL); Alexander Nikolov Zdravkov, Eindhoven (NL); Kornelis Tijmen Hoekerd, Eindhoven (NL); Nina Vladimirovna Dziomkina, Eindhoven (NL)

(72) Inventors: Raymond Wilhelmus Louis LAFARRE, Helmond (NL); Roelof Frederik De Graaf, Veldhoven (NL); Niek Jacobus Johannes Roset, Eindhoven (NL); Arjan Hubrecht Josef Anna Martens, Valkenburg (NL); Alexander Nikolov Zdravkov, Eindhoven (NL); Kornelis Tijmen Hoekerd, Eindhoven (NL); Nina Vladimirovna Dziomkina, Eindhoven (NL)

(21) Appl. No.: 13/623,790

(22) Filed: Sep. 20, 2012

Related U.S. Application Data
(60) Provisional application No. 61/538,011, filed on Sep. 22, 2011.

(51) Int. Cl. G03F 7/20; B32B 3/02; B08B 3/04

(52) U.S. Cl. CPC G03F 7/2041; B08B 3/04; B32B 3/02
USPC 355/30; 134/34; 428/189; 428/141

(57) ABSTRACT

A method and apparatus to clean a cover to seal a gap between an object located in a recess of a table and the upper surface of the table outside of the recess. In-line and off-line arrangements are disclosed. Cleaning can be carried out using abrasion, UV radiation or flushing with a cleaning fluid for example.

This application claims priority and benefit under 35 U.S.C. §119(e) to U.S. Provisional Patent Application No. 61/538,011, filed on Sep. 22, 2011. The content of that application is incorporated herein in its entirety by reference.

### FIELD

The present invention relates to a cleaning substrate for a lithography apparatus, a cleaning method for a lithography apparatus and a lithography apparatus.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

It has been proposed to immerse the substrate in the lithographic projection apparatus in a liquid having a relatively high refractive index, e.g. water, so as to fill a space between the final element of the projection system and the substrate. In an embodiment, the liquid is distilled water, although another liquid can be used. An embodiment of the invention will be described with reference to liquid. However, another fluid may be suitable, particularly a wetting fluid, an incompressible fluid and/or a fluid with higher refractive index than air, desirably a higher refractive index than water. Fluids excluding gases are particularly desirable. The point of this is to enable imaging of smaller features since the exposure radiation will have a shorter wavelength in the liquid. (The effect of the liquid may also be regarded as increasing the effective numerical aperture (NA) of the system and also increasing the depth of focus.) Other immersion liquids have been proposed, including water with solid particles (e.g. quartz) suspended therein, or a liquid with a nano-particle suspension (e.g. particles with a maximum dimension of up to 10 nm). The suspended particles may or may not have a similar or the same refractive index as the liquid in which they are suspended. Other liquids which may be suitable include a hydrocarbon, such as an aromatic, a fluorohydrocarbon, and/or an aqueous solution.

Submersing the substrate or substrate and substrate table in a bath of liquid (see, for example, U.S. Pat. No. 4,509,852) means that there is a large body of liquid that must be accelerated during a scanning exposure. This requires additional or more powerful motors and turbulence in the liquid may lead to undesirable and unpredictable effects.

In an immersion apparatus, immersion fluid is handled by a fluid handling system, device structure or apparatus. In an embodiment the fluid handling system may supply immersion fluid and therefore be a fluid supply system. In an embodiment the fluid handling system may at least partly confine immersion fluid and thereby be a fluid confinement system. In an embodiment the fluid handling system may provide a barrier to immersion fluid and thereby be a barrier member, such as a fluid confinement structure. In an embodiment the fluid handling system may create or use a flow of gas, for example to help in controlling the flow and/or the position of the immersion fluid. The flow of gas may form a seal to confine the immersion fluid so the fluid handling structure may be referred to as a seal member; such a seal member may be a fluid confinement structure. In an embodiment, immersion liquid is used as the immersion fluid. In that case the fluid handling system may be a liquid handling system. In reference to the aforementioned description, reference in this paragraph to a feature defined with respect to fluid may be understood to include a feature defined with respect to liquid.

### SUMMARY

The lithographic apparatus may be configured so that there is a gap, in use, between a substrate located in a recess in the substrate table and an upper surface of the substrate table that is peripherally outside of the substrate. The gap can act as a source of bubbles that may enter the immersion liquid above the substrate. The gap may allow contaminants to enter the region below the substrate. An apparatus to extract fluid through the gap may be provided. The extraction may help to prevent bubbles entering the immersion liquid above the substrate. However, the extraction process may cause a significant heat load on the substrate and/or substrate table, leading to overlay errors. A force interaction may occur between the fluid handling structure and a structure facing the fluid handling structure, such as a table (such as a substrate table) and/or a substrate which is supported by the substrate table. Fluid extracted from the gap may be in a two phase flow. Such a flow may cause force disturbances which may contribute to the force interaction between the facing structure and the fluid handling structure. Such force interaction may lead to a focus error, such as towards the edge of the substrate.

In order to address these and/or other technical challenges, a cover may be provided to cover the gap between the substrate (or other object) edge and the upper surface of a table, such as a substrate table. Such a cover may function as a seal to seal the gap from the entrance of liquid into the gap. However, when the cover comes into contact with the object and/or table there is a risk of contamination from particles that may be present on the object or table. A source of particles is a coating on the substrate, for example a resist and/or topcoat. Such a coating may be dislodged, e.g. peel, from the edge of the substrate.

Some or all of these particles may become attached to the cover. Such contamination on the cover may build up on the cover over time. The contamination could lead to a gap developing between the cover and the object and/or between the cover and the upper surface of the table (e.g. radially away from the substrate or other object) when the cover is in its closed position. This gap could prevent the cover from achieving an effective seal. If the seal is not properly established, bubbles could enter the immersion fluid in the region above the object. A flow of fluid past the seal could cause cooling of the object (e.g., the substrate) and/or table. Liquid could enter the region of a cover actuator and disrupt operation of the cover actuator. Liquid could enter the region beneath the object (e.g., the substrate). The risk of the cover engaging with a liquid confinement structure passing over the cover may be increased. Such engagement with a liquid confinement structure could cause the cover to be lifted up. Lifting of the cover could cause damage to the cover and/or the liquid confinement structure.

It is desirable, for example, to provide a method and apparatus that reduces the risk of degradation of the seal between the cover and the object and/or table.

According to an aspect, there is provided a cleaning substrate for a lithography apparatus, comprising: a base layer in the form of a disk having a diameter of 300 mm or 450 mm, to within a tolerance of 2%, and a maximum thickness of less than 2 mm; and an adhesive, abrasive or porous film formed on at least one of the major faces of the base layer, wherein the film is present within 0.5 mm of a peripheral edge of the disk.

According to an aspect, there is provided a cleaning method for a lithography apparatus, wherein the lithography apparatus comprises: a substrate table having an upper surface and a recess in the upper surface that is configured to receive and support a substrate; a fluid handling structure configured to supply and confine immersion fluid to a space adjacent to the upper surface of the substrate table and/or a substrate located in the recess; and a cover comprising a planar body that, in use, extends around a substrate from the upper surface to a peripheral section of an upper major face of the substrate in order to cover a gap between an edge of the recess and the edge of the substrate, wherein the method comprises: cleaning a surface of the cover.

According to an aspect, there is provided a cleaning method for a lithography apparatus, wherein the lithography apparatus comprises: a substrate table having an upper surface and a recess in the upper surface that is configured to receive and support a substrate; a fluid handling structure configured to supply and confine immersion fluid to a space adjacent to the upper surface of the substrate table and/or a substrate located in the recess; and a cover comprising a planar body that, in use, extends around a substrate from the upper surface to a peripheral section of an upper major face of the substrate in order to cover a gap between an edge of the recess and the edge of the substrate, wherein the method comprises: providing relative movement between the cover and a cleaning substrate located in the recess so as to bring the cover and the cleaning substrate into contact with each other and to remove the cover from contact with the cleaning substrate, to thereby clean the cover.

According to an aspect, there is provided a cleaning method for a lithography apparatus, wherein the lithography apparatus comprises: a substrate table having an upper surface and a recess in the upper surface that is configured to receive and support a substrate; a fluid handling structure configured to confine immersion fluid to a space adjacent to the upper surface of the substrate table and/or a substrate located in the recess; and a cover comprising a planar body that, in use, extends around a substrate from the upper surface to a peripheral section of an upper major face of the substrate in order to cover a gap between an edge of the recess and an edge of the substrate, wherein the method comprises: directing radiation onto the cover in order to clean the cover.

According to an aspect, there is provided a lithography apparatus comprising: a substrate table having an upper surface and a recess in the upper surface that is configured to receive and support a substrate; a fluid handling structure configured to confine immersion fluid in a space adjacent to the upper surface of the substrate table and/or a substrate located in the recess; a cover comprising a planar body that, in use, extends around a substrate from the upper surface to a peripheral section of an upper major face of the substrate in order to cover a gap between an edge of the recess and an edge of the substrate; and an abrasive member actuation system to hold an abrasive member and provide relative movement of the abrasive member against the cover.

According to an aspect, there is provided a lithography apparatus comprising: a substrate table having an upper surface and a recess in the upper surface that is configured to receive and support a substrate; a fluid handling structure configured to confine immersion fluid in a space adjacent to the upper surface of the substrate table and/or a substrate located in the recess; a cover comprising a planar body that, in use, extends around a substrate from the upper surface to a peripheral section of an upper major face of the substrate in order to cover a gap between an edge of the recess and an edge of the substrate; and a radiation outlet configured to direct radiation onto the cover.

According to an aspect, there is provided a lithography apparatus comprising: a substrate table having an upper surface and a recess in the upper surface that is configured to receive and support a substrate; a fluid handling structure configured to confine immersion fluid in a space adjacent to the upper surface of the substrate table and/or a substrate located in the recess; a cover comprising a planar body that, in use, extends around a substrate from the upper surface to a peripheral section of an upper major face of the substrate in order to cover a gap between an edge of the recess and an edge of the substrate; and a cover cleaning system to clean a surface of the cover.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIGS. 2 and 3 depict a liquid supply system for use in a lithographic projection apparatus;

FIG. 4 depicts a further liquid supply system for use in a lithographic projection apparatus;

FIG. 5 depicts a further liquid supply system for use in a lithographic projection apparatus;

FIG. 6 depicts, in cross-section, a further liquid supply system for use in a lithographic projection apparatus;

FIG. 7 depicts a cover to cover a gap between the substrate and an upper surface of a substrate table;

FIG. 8 depicts an example cleaning substrate geometry;

FIG. 9 depicts a cleaning substrate having an adhesive or porous film;

FIG. 10 depicts a cleaning substrate having an adhesive or porous film provided on an upper surface only;

FIG. 11 depicts a cleaning substrate in which rounding at an edge of the major face of the substrate is confined to within, for example, 0.5 mm of the edge and an adhesive or porous film is provided that extends to within, for example, 0.5 mm of the edge;

FIG. 12 depicts a cleaning substrate comprising a porous tip, or edge surface region;

FIG. 13 depicts a cleaning substrate having an adhesive or porous film formed on a beveled edge;

FIG. 14 depicts a cleaning substrate having a layer of colloidal particles (e.g. sol-gel) formed on a beveled edge;

FIG. 15 is a schematic side sectional view of a cleaning substrate having a ridge protruding from an upper face of the substrate;

FIG. 16 is a top view of the cleaning substrate of FIG. 15, showing the ridge forming a closed path that surrounds the axis of the cleaning substrate;

FIG. 17 is a top view of a portion of a cleaning substrate in which a plurality of radially aligned ridges are provided;

FIG. 18 is a radially inward view of the cleaning substrate shown in FIG. 17;

FIG. 19 is a top view of a portion of a cleaning substrate comprising a plurality of structures formed from intersecting ridges;

FIG. 20 is a top view of a portion of a cleaning substrate in which the ridges form closed paths that do not surround the axis of the cleaning substrate;

FIG. 21 depicts a cover spanning a gap between a substrate and the upper surface of a substrate table;

FIG. 22 depicts an abrasive member actuation system configured to hold a cleaning substrate and move the cleaning substrate so as to scrape against the cover;

FIG. 23 depicts use of a substrate table actuator and support pins to provide relative motion between a cleaning substrate and the cover;

FIG. 24 depicts an abrasive member actuation system configured to hold a scalpel or brush and move the scalpel or brush so as to scrape against the cover;

FIG. 25 depicts an arrangement in which a cleaning substrate having a larger thickness or radius than a production substrate is provided to assist cleaning of the cover;

FIG. 26 depicts an arrangement to clean an underside of the cover by reflecting radiation off the substrate;

FIG. 27 depicts an arrangement in which the radiation is reflected from a reflective element formed on the edge of a substrate;

FIG. 28 depicts an arrangement in which radiation is reflected from a reflective element formed in the upper surface of the table onto the cover;

FIG. 29 depicts an arrangement in which radiation is directed onto the cover using an optical fiber;

FIG. 30 illustrates an arrangement in which a fluid flow is provided between the region above the cover and the region below the cover in order to clean the cover;

FIG. 31 depicts an arrangement in which a fluid flow is provided from the region below the cover to the region above the cover in order to clean the cover; and

FIG. 32 depicts a cleaning substrate comprising a charge holding member.

### DETAILED DESCRIPTION

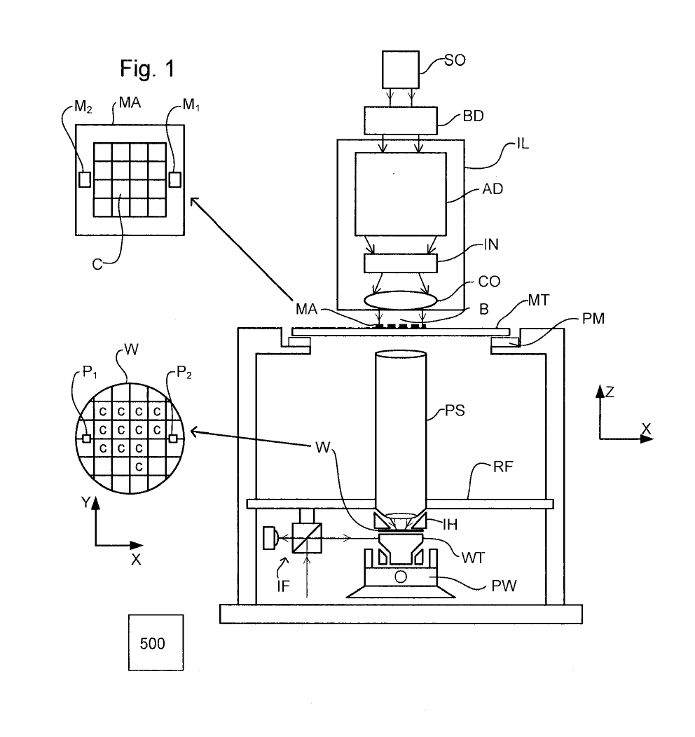

FIG. 1 schematically depicts a lithographic apparatus according to one embodiment of the invention. The apparatus comprises:
an illumination system (illuminator) IL configured to condition a radiation beam B (e.g. UV radiation or DUV radiation);
a support structure (e.g. a mask table) MT constructed to support a patterning device (e.g. a mask) MA and connected to a first positioner PM configured to accurately position the patterning device MA in accordance with certain parameters;
a support table, e.g. table to support one or more objects, for example a sensor table to support one or more sensors or a substrate table WT constructed to hold a substrate (e.g. a resist-coated substrate) W optionally with one or more sensors, connected to a second positioner PW configured to accurately position the surface of the table, for example of a substrate W, in accordance with certain parameters; and
a projection system (e.g. a refractive projection lens system) PS configured to project a pattern imparted to the radiation beam B by patterning device MA onto a target portion C (e.g. comprising one or more dies) of the substrate W.

The illumination system IL may include various types of optical components, such as refractive, reflective, magnetic, electromagnetic, electrostatic or other types of optical components, or any combination thereof, for directing, shaping, or controlling radiation.

The support structure MT holds the patterning device MA. It holds the patterning device MA in a manner that depends on the orientation of the patterning device MA, the design of the lithographic apparatus, and other conditions, such as for example whether or not the patterning device MA is held in a vacuum environment. The support structure MT can use mechanical, vacuum, electrostatic or other clamping techniques to hold the patterning device MA. The support structure MT may be a frame or a table, for example, which may be fixed or movable as required. The support structure MT may ensure that the patterning device MA is at a desired position, for example with respect to the projection system PS. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device MA may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g. employing a transmissive mask). Alternatively, the apparatus may be of a reflective type (e.g. employing a programmable mirror array of a type as referred to above, or employing a reflective mask).

The lithographic apparatus may be of a type having two or more tables (or stages or supports), e.g., two or more substrate tables or a combination of one or more substrate tables and one or more cleaning, sensor or measurement tables. For example, in an embodiment, the lithographic apparatus is a multi-stage apparatus comprising two or more tables located at the exposure side of the projection system, each table comprising and/or holding one or more objects. In an embodiment, one or more of the tables may hold a radiation-sensitive substrate. In an embodiment, one or more of the tables may hold a sensor to measure radiation from the projection system. In an embodiment, the multi-stage apparatus comprises a first table configured to hold a radiation-sensitive substrate (i.e., a substrate table) and a second table not configured to hold a radiation-sensitive substrate (referred to hereinafter generally, and without limitation, as a measurement, sensor and/or cleaning table). The second table may comprise and/or may hold one or more objects, other than a radiation-sensitive substrate. Such one or more objects may include one or more selected from the following: a sensor to measure radiation from the projection system, one or more alignment marks, and/or a cleaning device (to clean, e.g., the liquid confinement structure).

In such “multiple stage” (or “multi-stage”) machines the multiple tables may be used in parallel, or preparatory steps may be carried out on one or more tables while one or more other tables are being used for exposure. The lithographic apparatus may have two or more patterning device tables (or stages or support) which may be used in parallel in a similar manner to substrate, cleaning, sensor and/or measurement tables.

In an embodiment, the lithographic apparatus may comprise an encoder system to measure the position, velocity, etc. of a component of the apparatus. In an embodiment, the component comprises a substrate table. In an embodiment, the component comprises a measurement and/or sensor and/or cleaning table. The encoder system may be in addition to or an alternative to the interferometer system described herein for the tables. The encoder system comprises a sensor, transducer or readhead associated, e.g., paired, with a scale or grid. In an embodiment, the movable component (e.g., the substrate table and/or the measurement and/or sensor and/or cleaning table) has one or more scales or grids and a frame of the lithographic apparatus with respect to which the component moves has one or more of sensors, transducers or readheads. The one or more of sensors, transducers or readheads cooperate with the scale(s) or grid(s) to determine the position, velocity, etc. of the component. In an embodiment, a frame of the lithographic apparatus with respect to which a component moves has one or more scales or grids and the movable component (e.g., the substrate table and/or the measurement and/or sensor and/or cleaning table) has one or more of sensors, transducers or readheads that cooperate with the scale(s) or grid(s) to determine the position, velocity, etc. of the component.

Referring to FIG. 1, the illuminator IL receives a radiation beam from a radiation source SO. The source SO and the lithographic apparatus may be separate entities, for example when the source SO is an excimer laser. In such cases, the source SO is not considered to form part of the lithographic apparatus and the radiation beam is passed from the source SO to the illuminator IL with the aid of a beam delivery system BD comprising, for example, suitable directing mirrors and/or a beam expander. In other cases the source SO may be an integral part of the lithographic apparatus, for example when the source SO is a mercury lamp. The source SO and the illuminator IL, together with the beam delivery system BD if required, may be referred to as a radiation system.

The illuminator IL may comprise an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator IL can be adjusted. In addition, the illuminator IL may comprise various other components, such as an integrator IN and a condenser CO. The illuminator IL may be used to condition the radiation beam, to have a desired uniformity and intensity distribution in its cross-section. Similar to the source SO, the illuminator IL may or may not be considered to form part of the lithographic apparatus. For example, the illuminator IL may be an integral part of the lithographic apparatus or may be a separate entity from the lithographic apparatus. In the latter case, the lithographic apparatus may be configured to allow the illuminator IL to be mounted thereon. Optionally, the illuminator IL is detachable and may be separately provided (for example, by the lithographic apparatus manufacturer or another supplier).

The radiation beam B is incident on the patterning device (e.g., mask) MA, which is held on the support structure (e.g., mask table) MT, and is patterned by the patterning device MA. Having traversed the patterning device MA, the radiation beam B passes through the projection system PS, which focuses the beam onto a target portion C of the substrate W. With the aid of the second positioner PW and position sensor IF (e.g. an interferometric device, linear encoder or capacitive sensor), the substrate table WT can be moved accurately, e.g. so as to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner) the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions C (these are known as scribe-lane alignment marks). Similarly, in situations in which more than one die is provided on the patterning device MA, the patterning device alignment marks may be located between the dies.

The depicted apparatus could be used in at least one of the following modes:

1. In step mode, the support structure MT and the substrate table WT are kept essentially stationary, while an entire pattern imparted to the radiation beam B is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure.

2. In scan mode, the support structure MT and the substrate table WT are scanned synchronously while a pattern imparted to the radiation beam B is projected onto a target portion C (i.e. a single dynamic exposure). The velocity and direction of the substrate table WT relative to the support structure MT may be determined by the (de-)magnification and image reversal characteristics of the projection system PS. In scan mode, the maximum size of the exposure field limits the width (in the non-scanning direction) of the target portion C in a single dynamic exposure, whereas the length of the scanning motion determines the height (in the scanning direction) of the target portion C.

3. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

Although specific reference may be made in this text to the use of lithographic apparatus in the manufacture of ICs, it should be understood that the lithographic apparatus described herein may have other applications in manufacturing components with microscale, or even nanoscale, features, such as the manufacture of integrated optical systems, guidance and detection patterns for magnetic domain memories, flat-panel displays, liquid-crystal displays (LCDs), thin-film magnetic heads, etc.

Arrangements for providing liquid between a final element of the projection system PS and the substrate can be classed into three general categories. These are the bath type arrangement, the so-called localized immersion system and the all-wet immersion system. In a bath type arrangement substantially the whole of the substrate W and optionally part of the substrate table WT is submersed in a bath of liquid

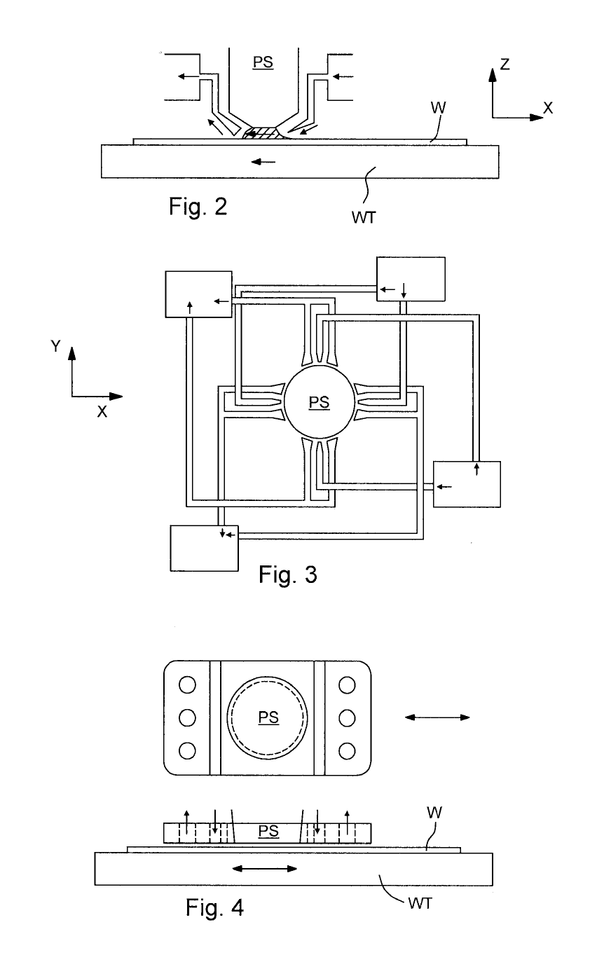

A localized immersion system uses a liquid supply system in which liquid is only provided to a localized area of the substrate. The space filled by liquid is smaller in plan than the top surface of the substrate and the area filled with liquid remains substantially stationary relative to the projection system PS while the substrate W moves underneath that area. FIGS. 2-6 show different supply devices which can be used in such a system. A sealing feature is present to seal liquid to the localized area. One way which has been proposed to arrange for this is disclosed in PCT Patent Application Publication No. WO 99/49504.

In an all wet arrangement the liquid is unconfined. The whole top surface of the substrate and all or part of the substrate table is covered in immersion liquid. The depth of the liquid covering at least the substrate is small. The liquid may be a film, such as a thin film, of liquid on the substrate. Immersion liquid may be supplied to or in the region of a projection system and a facing surface facing the projection system (such a facing surface may be the surface of a substrate and/or a substrate table). Any of the liquid supply devices of FIGS. 2-5 can also be used in such a system. However, a sealing feature is not present, not activated, not as efficient as normal or otherwise ineffective to seal liquid to only the localized area.

As illustrated in FIGS. 2 and 3, liquid is supplied by at least one inlet onto the substrate, desirably along the direction of movement of the substrate relative to the final element. Liquid is removed by at least one outlet after having passed under the projection system. As the substrate is scanned beneath the element in a −X direction, liquid is supplied at the +X side of the element and taken up at the −X side. FIG. 2 shows the arrangement schematically in which liquid is supplied via inlet and is taken up on the other side of the element by outlet which is connected to a low pressure source. In the illustration of FIG. 2 the liquid is supplied along the direction of movement of the substrate relative to the final element, though this does not need to be the case. Various orientations and numbers of in- and out-lets positioned around the final element are possible; one example is illustrated in FIG. 3 in which four sets of an inlet with an outlet on either side are provided in a regular pattern around the final element. Note that the direction of flow of the liquid is shown by arrows in FIGS. 2 and 3.

A further immersion lithography solution with a localized liquid supply system is shown in FIG. 4. Liquid is supplied by two groove inlets on either side of the projection system PS and is removed by a plurality of discrete outlets arranged radially outwardly of the inlets. The inlets can be arranged in a plate with a hole in its centre and through which the projection beam is projected. Liquid is supplied by one groove inlet on one side of the projection system PS and removed by a plurality of discrete outlets on the other side of the projection system PS, causing a flow of a thin film of liquid between the projection system PS and the substrate W. The choice of which combination of inlet and outlets to use can depend on the direction of movement of the substrate W (the other combination of inlet and outlets being inactive). Note that the direction of flow of fluid and of the substrate is shown by arrows in FIG. 4.

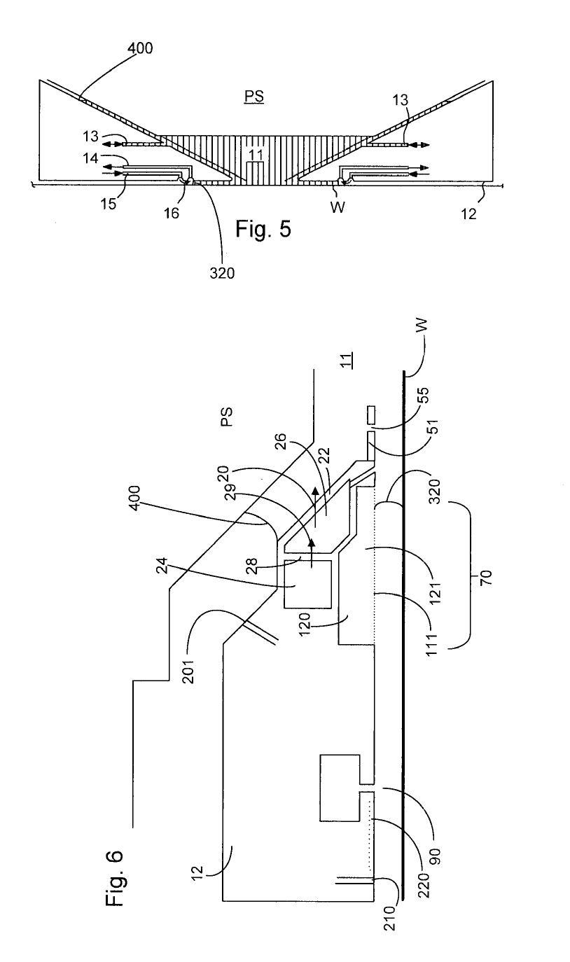

Another arrangement which has been proposed is to provide the liquid supply system with a liquid confinement structure which extends along at least a part of a boundary of the space between the final element of the projection system and the substrate table. Such an arrangement is illustrated in FIG. 5.

In an embodiment, the lithographic apparatus comprises a liquid confinement structure that has a liquid removal device having an inlet covered with a mesh or similar porous material. The mesh or similar porous material provides a two-dimensional array of holes contacting the immersion liquid in a space between the final element of the projection system and a movable table (e.g., the substrate table). In an embodiment, the mesh or similar porous material comprises a honeycomb or other polygonal mesh. In an embodiment, the mesh or similar porous material comprises a metal mesh. In an embodiment, the mesh or similar porous material extends all the way around the image field of the projection system of the lithographic apparatus. In an embodiment, the mesh or similar porous material is located on a bottom surface of the liquid confinement structure and has a surface facing towards the table. In an embodiment, the mesh or similar porous material has at least a portion of its bottom surface generally parallel with a top surface of the table.

FIG. 5 schematically depicts a localized liquid supply system or liquid handling structure 12, which extends along at least a part of a boundary of the space between the final element of the projection system and the substrate table WT or substrate W. (Please note that reference in the following text to surface of the substrate W also refers in addition or in the alternative to a surface of the substrate table, unless expressly stated otherwise. Reference to substrate table WT includes reference to a sensor located on the substrate table, unless expressly stated otherwise) The liquid handling structure 12 is substantially stationary relative to the projection system in the XY plane though there may be some relative movement in the Z direction (in the direction of the optical axis). In an embodiment, a seal is formed between the liquid handling structure 12 and the surface of the substrate W and may be a contactless seal such as a gas seal (such a system with a gas seal is disclosed in European Patent Application Publication No. EP-A-1,420,298) or liquid seal.

The liquid handling structure 12 at least partly contains liquid in the space 11 between a final element of the projection system PS and the substrate W. A contactless seal 16 to the substrate W may be formed around the image field of the projection system PS so that liquid is confined within the space between the substrate W surface and the final element of the projection system PS. The space 11 is at least partly formed by the liquid handling structure 12 positioned below and surrounding the final element of the projection system PS. Liquid is brought into the space below the projection system PS and within the liquid handling structure 12 by liquid inlet 13. The liquid may be removed by liquid outlet 13. The liquid handling structure 12 may extend a little above the final element of the projection system. The liquid level rises above the final element so that a buffer of liquid is provided, the buffer of liquid defined by a meniscus 400. In an embodiment, the liquid handling structure 12 has an inner periphery that at the upper end closely conforms to the shape of the projection system or the final element thereof and may, e.g., be round. At the bottom, the inner periphery closely conforms to the shape of the image field, e.g., rectangular, though this need not be the case.

The liquid may be contained in the space 11 by a gas seal 16 which, during use, is formed between the bottom of the liquid handling structure 12 and the surface of the substrate W. The gas seal is formed by gas. The gas in the gas seal is provided under pressure via inlet 15 to the gap between the liquid handling structure 12 and substrate W. The gas is extracted via outlet 14. The overpressure on the gas inlet 15, vacuum level on the outlet 14 and geometry of the gap are arranged so that there is a high-velocity gas flow 16 inwardly that confines the liquid. The force of the gas on the liquid between the liquid handling structure 12 and the substrate W contains the liquid in a space 11 and allows formation of a meniscus 320. The inlets/outlets may be annular grooves which surround the space 11. The annular grooves may be continuous or discontinuous. The flow of gas 16 is effective to contain the liquid in the space 11. Such a system is disclosed in United States Patent Application Publication No. US 2004-0207824, which is hereby incorporated by reference in its entirety. In an embodiment, the liquid handling structure 12 does not have a gas seal, but may have a contactless seal other than a gas seal.

FIG. 6 illustrates a liquid handling structure 12 which is part of a liquid supply system. The liquid handling structure 12 extends around the periphery (e.g. circumference) of the final element of the projection system PS. A plurality of openings 20 in the surface which in part defines the space 11 provides the liquid to the space 11. The liquid passes through openings 29, 20 in side walls 28, 22 respectively through respective chambers 24, 26 prior to entering the space 11.

A seal is provided between the bottom of the liquid handling structure 12 and a facing surface, e.g. the substrate W, or a substrate table WT, or both. In FIG. 6 a seal device is configured to provide a contactless seal and is made up of several components. Radially outwardly from the optical axis of the projection system PS, there is provided a (optional) flow control plate 51 which extends into the space 11. The control plate 51 may have an opening 55 to permit flow liquid therethrough; the opening 55 may be beneficial if the control plate 51 is displaced in the Z direction (e.g., parallel to the optical axis of the projection system PS).

Radially outwardly of the control plate 51 may be an extractor assembly 70 to extract liquid from between the liquid handling structure 12 and the facing surface. The extractor assembly 70 may operate as a single phase or as a dual phase extractor. The extractor assembly 70 acts as a meniscus pinning feature of a meniscus 320 of the liquid.

Radially outwardly of the extractor assembly may be a gas knife 90. An arrangement of the extractor assembly and gas knife is disclosed in detail in United States Patent Application Publication No. US 2006/0158627 incorporated herein in its entirety by reference.

The extractor assembly 70 as a single phase extractor may comprise a liquid removal device, extractor or inlet such as the one disclosed in United States Patent Application Publication No. US 2006-0038968, incorporated herein in its entirety by reference. In an embodiment, the liquid removal device 70 comprises an inlet which is covered in a porous material 111 which is used to separate liquid from gas to enable single-liquid phase liquid extraction. An under pressure in chamber 121 is chosen is such that the meniscuses formed in the holes of the porous material 111 prevent ambient gas from being drawn into the chamber 121 of the liquid removal device 70. However, when the surface of the porous material 111 comes into contact with liquid there is no meniscus to restrict flow and the liquid can flow freely into the chamber 121 of the liquid removal device 70.

The porous material 111 has a large number of small holes each with a dimension, e.g. a width, such as a diameter, in the range of 5 to 100 micrometers, desirably 5 to 50 micrometers. The porous material 111 may be maintained at a height in the range of 50 to 300 micrometers above a surface, such as a facing surface, from which liquid is to be removed, e.g. the surface of a substrate W. In an embodiment, porous material 111 is at least slightly liquidphilic, i.e. having a dynamic contact angle of less than 90°, desirably less than 85° or desirably less than 80°, to the immersion liquid, e.g. water.

Radially outward of gas knife 90 may be provided one or more outlets 210 to remove gas from gas knife 90 and/or liquid that may escape past the gas knife 90. The one or more outlets 210 may be located between one or more outlets of the gas knife 90. To facilitate channeling of fluid (gas and/or liquid) to the outlet 210, a recess 220 may be provided in the liquid confinement structure 12 that is directed toward outlet 210 from outlets of the gas knife 90 and/or from between outlets of the gas knife 90.

Although not specifically illustrated in FIG. 6, the liquid supply system has an arrangement to deal with variations in the level of the liquid. This is so that liquid which builds up between the projection system PS and the liquid confinement structure 12 (and forms a meniscus 400) can be dealt with and does not escape. One way of dealing with this liquid is to provide a lyophobic (e.g., hydrophobic) coating. The coating may form a band around the top of the fluid handling structure 12 surrounding the opening and/or around the last optical element of the projection system PS. The coating may be radially outward of the optical axis of the projection system PS. The lyophobic (e.g., hydrophobic) coating helps keep the immersion liquid in the space 11. Additionally or alternatively, one or more outlets 201 may be provided to remove liquid reaching a certain high relative to the structure 12.

Another localized area arrangement is a liquid handling structure which makes use of a gas drag principle. The so-called gas drag principle has been described, for example, in United States Patent Application Publication Nos. US 2008-0212046, US 2009-0279060 and US 2009-0279062. In that system the extraction holes are arranged in a shape which may desirably have a corner. The corner may be aligned with a preferred direction of movement, such as the stepping or the scanning direction. This reduces the force on the meniscus between two openings in the surface of the liquid handing structure for a given speed in the preferred direction compared to if the two outlets were aligned perpendicular to the preferred direction. However, an embodiment of the invention may be applied to a liquid handling system which in plan has any shape, or has a component such as the extraction openings arranged in any shape. Such a shape in a non-limiting list may include an ellipse such as a circle, a rectilinear shape such as a rectangle, e.g. a square, or a parallelogram such as a rhombus or a cornered shape with more than four corners such as a four or more pointed star.

In a variation of the system of US 2008/0212046 A1, to which an embodiment of the present invention may relate, the geometry of the cornered shape in which the openings are arranged allows sharp corners (between about 60° and 90°, desirably between 75° and 90° and most desirably between 75° and 85°) to be present for the corners aligned both in the scan and in the stepping directions. This allows increased speed in the direction of each aligned corner. This is because the creation of liquid droplets due to an unstable meniscus, for example in exceeding a critical speed, in the scanning direction is reduced. Where corners are aligned with both the scanning and stepping directions, increased speed may be achieved in those directions. Desirably the speed of movement in the scanning and stepping directions may be substantially equal.

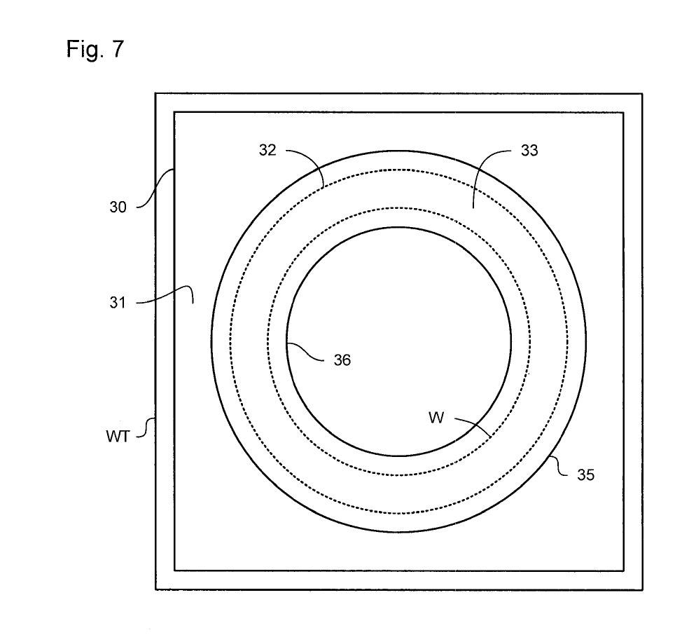

FIG. 7 depicts, in plan view, a substrate table WT that may be used to support a substrate W. The substrate table may have a substantially planar upper surface 31. In the upper surface 31 is a recess 32 that is configured to receive and support a substrate W.

In the recess may be a substrate support which may be a surface of the recess. The surface of the recess 32 may include a plurality of protrusions on which a lower surface of the substrate is supported. The surface of the recess may include a barrier. In the surface of the recess may be formed a plurality of openings. The barrier surrounds the protrusions to define a space beneath the lower surface of the substrate W. The openings are connected to an under-pressure source. When a substrate is located above the openings a space is formed beneath the substrate W. The space may be evacuated by operation of the underpressure. This arrangement may be used in order to secure the substrate W to the substrate table WT.

In an arrangement, the recess may be configured such that the major faces of the substrate, namely the upper face and the lower face, are substantially parallel to the upper surface 31 of the substrate table. In an arrangement, the upper face of the substrate W may be arranged to be substantially coplanar with upper surface 31 of the substrate table.

In the present application, terms such as upper and lower may be used in order to define the relative positions of components within the systems described. However, these terms are used for convenience in order to describe the relative positions of the components when the apparatus is used at a particular orientation. They are not intended to specify the orientation in which the apparatus may be used.

As depicted in FIG. 7, a gap 33 may be present between an edge of the substrate W and an edge of the recess 32. A cover 35 is provided that extends around the substrate W. The cover 35 extends from a peripheral section of the upper surface of the substrate W (which in an embodiment may be an edge of the substrate) to the upper surface 31 of the substrate table WT. The cover 35 may entirely cover the gap 33 between the edge of the substrate W and the edge of the recess 32. An open central section 36 of the cover 35 may be defined by an inner edge of the cover. The open central section 36 may be arranged such that, in use, the cover 35 does not cover portions of the substrate W on which it is intended to project a patterned beam of radiation. The inner edge of the cover may cover portions of the substrate which neighbor the surface of the substrate which is imaged by the patterned projection beam. The cover is located away from those portions of the substrate which are exposed by the patterned projection beam. The cover may have one or more radial breaks which permit the cover to open when it is raised from the surface of the table, thereby allowing ingress and egress of the substrate from the recess 32. The cover is described in further detail in U.S. Patent Application Publication No. US 2011-0013169, U.S. Patent Application Publication No. US 2011-0228248, and U.S. Patent Application Publication No. US 2011-0228238, each hereby incorporated by reference in its entirety.

As shown in FIG. 7, when the cover 35 is placed on the substrate W, the size of the open central section 36 may be slightly smaller than the size of the upper surface of the substrate W. As shown in FIG. 7, if the substrate W is circular in shape, the cover 35 may be generally annular in shape when viewed in plan view.

The cover 35 may be in the form of a thin cover plate. The cover plate may, for example, be formed from stainless steel. Other material may be used. The cover plate may be coated with Lipocer coating of the type offered by Plasma Electronic GmbH. Lipocer is a coating which may be lyophobic (e.g. hydrophobic) and is relatively resistant to damage from exposure to radiation and immersion liquid (which may be highly corrosive). The Lipocer may also disfavor adhesion of contaminant particles to the cover 35. More information on Lipocer may be found in U.S. Patent Application Publication No. US 2009-0206304, which is hereby incorporated by reference in its entirety.

As mentioned above, contaminant particles may build up on the cover 35 over time. The contaminant particles may prevent the cover 35 from establishing a seal with the substrate W and/or with the upper surface 31 of the substrate table WT. One or more steps may be taken to reduce the degree of contamination. For example, the peripherally outer regions of a production substrate (i.e. a region of a substrate surface that directly contacts the cover 35) could be cleaned to a higher degree than is standard practice. However it is difficult to eradicate contamination. A source of contamination is a coating of the substrate. Cleaning of the substrate surface increases the risk of generating contaminating particles.

In an embodiment, a cleaning substrate is provided that has a dimension the same as or similar to a production substrate. For example, the cleaning substrate may have a diameter that is within 2% of the diameter of a production substrate for the lithography apparatus in which the cleaning substrate is to be used. Such a cleaning substrate can be introduced into the region of the cover 35 in the same (or similar) way as a production substrate. For example, the cleaning substrate may be positioned in the same recess 32 of the substrate table WT as a production substrate W. The cleaning substrate may be handled by the same apparatus that is used to handle production substrates, with no or minimal modification. The cleaning substrate can therefore be used to provide in-line cleaning of the cover 35 with no or minimal modification of the lithography apparatus.

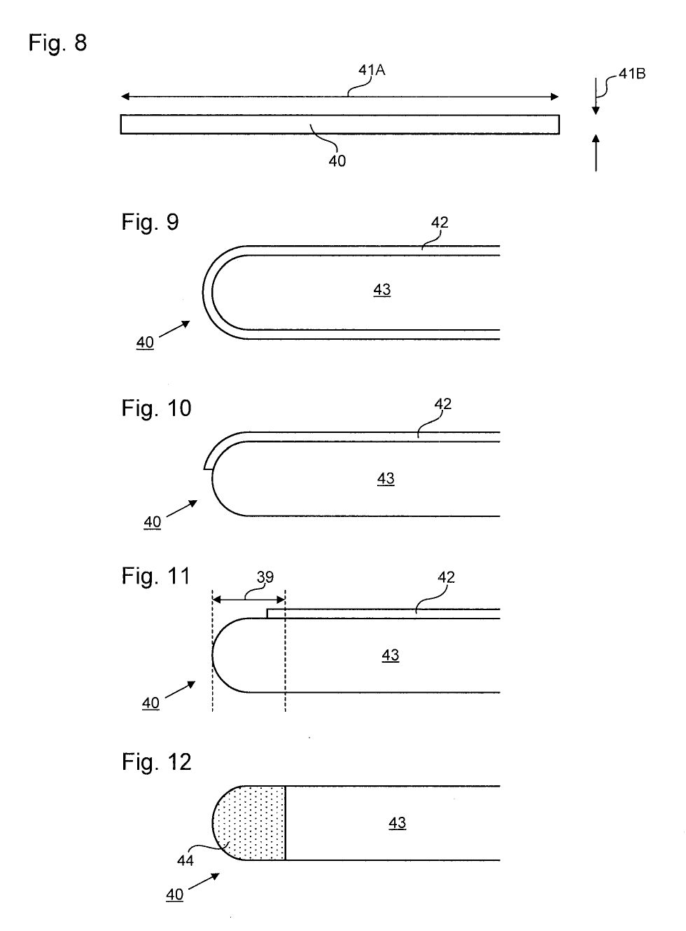

FIG. 8 illustrates an example geometry of a cleaning substrate 40. In an embodiment, the cleaning substrate 40 comprises a base layer in the form of a disk having a width (e.g., diameter) 41A of 300 mm or 450 mm, for example. The widths 300 mm and 450 mm correspond to standard diameters of production substrates in commercially available or commercially envisaged lithography machines. Where the lithography apparatus is configured to use production substrates having a different width (e.g., diameter), the cleaning substrate 40 may be provided with a base layer having this different width. In an embodiment, the base layer has a maximum thickness 41B of less than 1 mm. In an embodiment, the thickness of the base layer is substantially the same as the thickness of the production substrate for the lithography apparatus with which the cleaning substrate 40 is to be used. For example, the thickness of the base layer may be the same as the thickness of the production substrate of the lithography apparatus to within 5%. For example, the thickness of the base layer may be 775 microns to within 5%.

FIG. 9 is a schematic sectional side view of a peripheral edge of a cleaning substrate 40 comprising a film 42 on the base layer 43. In an embodiment, the film 42 is an adhesive or porous film 42. In an embodiment, the film 42 is an abrasive film 42. The film 42 may be configured to dislodge and/or retain organic particles, inorganic particles, or both. The film 42 may comprise a sponge or sticky film. The film 42 may be formed from inorganic material or organic material. In an embodiment, the base layer 43 is completely encapsulated by the film 42, as in the depicted example. Alternatively, the base layer 43 may be only partially encapsulated by the film 42.

FIG. 10 shows an example embodiment in which the base layer 43 is provided with the film 42 on only one of the major faces of the base layer 43. In an embodiment, the film 42 covers a peripheral edge of the base layer 43; the radial inward major surfaces of the base layer 43 may be film free.

FIG. 11 depicts an example embodiment in which the base layer 43 is provided with a film 42 that extends radially to a position within a distance 39 of the edge of the base layer 43. In embodiments of this type the film 42 is absent from the peripheral edge. The absence of film 42 may facilitate handling of the cleaning substrate 40. For example, the absence of the film 42 may prevent contamination of handling apparatus by the film 42. Alternatively or additionally, the absence of the film may prevent damage of the film 42 by a handling apparatus.

In an embodiment, the distance 39 is less than or equal to 0.5 mm, desirably less than or equal to 0.4 mm, or more desirably less than or equal to 0.25 mm. In an embodiment, the distance 39 is smaller than the overlap between the cover 35 and a production substrate located within the recess when the cover 35 is positioned so as to cover the gap between the edge of the recess and the production substrate. Thus, lowering of the cover 35 into position across the gap, when a cleaning substrate according to such an embodiment is located in the recess, will cause the cover 35 to be brought into contact with the film 42. The film 42 may be present over all of one face of the cleaning substrate (the upper face in use) or may be restricted to the region near the periphery where the cleaning substrate will contact the cover 35.

In an embodiment, the film 42 may be absent from non-planar regions at the peripheral edge of the base layer 43. For example, where the peripheral edge of the base layer 43 is rounded or beveled, the film 42 may be absent from the region of rounding or beveling. FIG. 11 shows an example embodiment of this type. Forming the film 42 only on planar parts of the base layer 43 may assist with manufacturing of the cleaning substrate 40 and/or with reliability of the cleaning substrate 40.

In an embodiment, the film 42 may comprise one or more of the following: hexamethyldisilazane (HDMS), colloidal particles, and/or sol-gel particles. The HDMS, colloidal particles or sol-gel particles may be formed in a very thin layer, such as a monolayer. The colloidal particles (e.g. sol-gel particles) may have an average diameter of less than or equal to 10 microns, desirably less than or equal to 1 micron, or desirably less than or equal to 100 nm. Making the film 42 very thin reduces the risk of contaminant particles being generated by the film 42. To achieve adequate adhesive qualities, the static contact angle with liquid (e.g. water) may be lyophilic (e.g., hydrophilic), for example about 50 degrees or less. A low contact angle tends to favor adhesion. For example, a low contact angle with water will tend to allow formation of a layer of water on the surface. Contaminant particles will tend to adhere to a layer of water by capillary forces.

In an embodiment, the film 42 is formed by depositing a two-phase inorganic film on the substrate and subsequently removing one of the phases to leave a porous, for example sponge-like, one-phase material behind. In an embodiment of this type, the degree of porosity can be controlled by controlling the volume of the phase that is removed. A porous film of this type can be organic or inorganic.

In an embodiment, the film 42 is formed by melting (by heating) inorganic particles on top of the substrate to form a porous film. In an embodiment of this type, a plurality of the particles having substantially the same size can used. In other embodiments of this type, a plurality of particles having a distribution of different sizes can be used.

In an embodiment, rounding or beveling at the edge of the base layer 43 is constrained so as to be present only within the region 39 of the edge of the base layer 43. Constraining the rounded/beveled region in this manner increases the extent to which a planar surface of the cleaning substrate 40 can be brought into contact with the cover 35. In the example of FIG. 11, the constrained rounded portion is provided in combination with a film 42, but this is not essential. Any of the cleaning substrate configurations disclosed herein may be provided with a constrained rounded or beveled edge.

FIG. 12 illustrates an example embodiment in which an edge surface region 44 of the base layer 43 is treated so as to be porous relative to the rest of the base layer 43. For example, the region 44 may be roughened relative to other regions of the base layer 43. Increasing the porosity of region 44 may increase the capacity of the region 44 to store contaminants, such as particles, extracted from the surface of the cover 35. In an embodiment, contaminant particles may be trapped within the holes of the porous structure for example. Additionally or alternatively, the porous region 44 may have a higher coefficient of friction than other regions of the base layer 43, which may assist in removing contaminants from the cover 35. In other embodiments other regions of the base layer 43 are made more porous (for example relative to an untreated substrate, e.g. a plain silicon wafer). In an embodiment, the entire base layer is made more porous. In an embodiment, a porous ceramic layer is applied to the base layer.

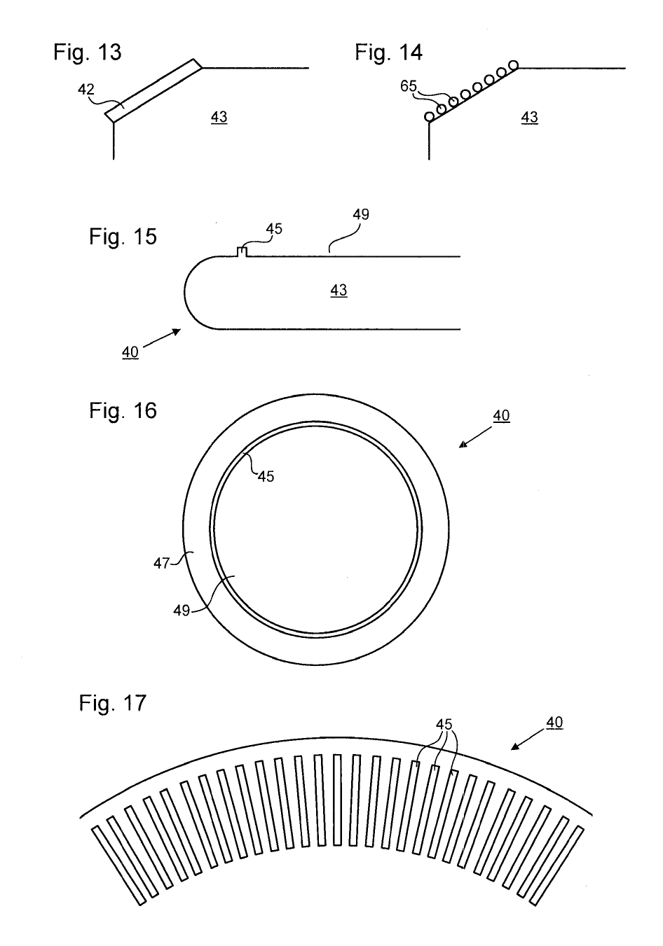

FIGS. 13 and 14 are schematic side section views of the edge of the base layer 43 of a cleaning substrate 40. The Figures each show an edge of base layer 43 having a straight beveled edge. In an embodiment, the angle of beveling is between 30 and 70 degrees. In the example of FIG. 13, a film 42 as described herein is provided on the beveled edge. In the example of FIG. 14, a plurality of particles 65 are attached to the beveled edge. The particles 65 may be colloidal particles, for example sol-gel particles. The particles may be attached to the surface during a heating process. The particles 65 may be configured to conform to the shape of the cover 35 when the cleaning substrate 40 is brought into contact with the cover 35 to improve cleaning efficiency. The particles 65 may provide adhesive properties. The gaps between particles 65 may form enclosed regions to contain and remove contaminants, such as in the form a particle, from the surface of the cover 35. In other embodiments, the film 42 or the particles 65 may be formed on the planar part of the cleaning substrate, for example adjacent to the beveled edge. In an embodiment, the film 42 or particles 65 are formed on the beveled edge and on a planar part of the cleaning substrate, for example adjacent to the beveled edge.

FIGS. 15 and 16 are sectional side and top views respectively of an embodiment of a cleaning substrate 40 that has an enclosed region 49 formed on top of the base layer 43. In an embodiment, the enclosed region 49 is defined by a ridge 45 protruding from the upper face of the base layer 43 with optionally a beveled region 47 outward of the ridge 45. The ridge may have a thickness of less than or equal to 20 microns for example, desirably less than or equal to 10 microns, desirably in the range of 1 micron to 2 microns. The outer edge (the ridge 45 in the example shown) may form a partially or completely closed path that surrounds the axis of the cleaning substrate 40. In the example shown in FIG. 16, the axis of the cleaning substrate 40 protrudes vertically (out of the page) from the centre of the circle representing the cleaning substrate 40. The ridge 45 in this example forms a closed path that surrounds this axis. In an embodiment, the ridge 45 follows an annular path near to the edge of the base layer 43. Desirably, the ridge 45 forms an annular path within 3 mm of the edge of the substrate, desirably within 1 mm, more desirably within 0.5 mm, or more desirably within 0.25 mm. When the substrate is placed in the recess 32, the cover 35 may contact the ridge 45.

An enclosed region 49 is useful because it provides a region within which contaminants scraped off the cover 35 may be contained. The contained contaminants may be removed from the surface of the cover 35 onto the substrate 40. The cleaning substrate 40 and the cover 35 may be moved relative to each other, for example by moving the substrate relative to the cover 35, so that the ridge 45 is scraped against the cover 35 in a radial direction. Optionally the relative motion between the substrate 40 and the cover 35 may be such that the ridge 45 may be scraped in a radially inward direction in the frame of reference of the cover so that contaminants fall into the enclosed region 49.

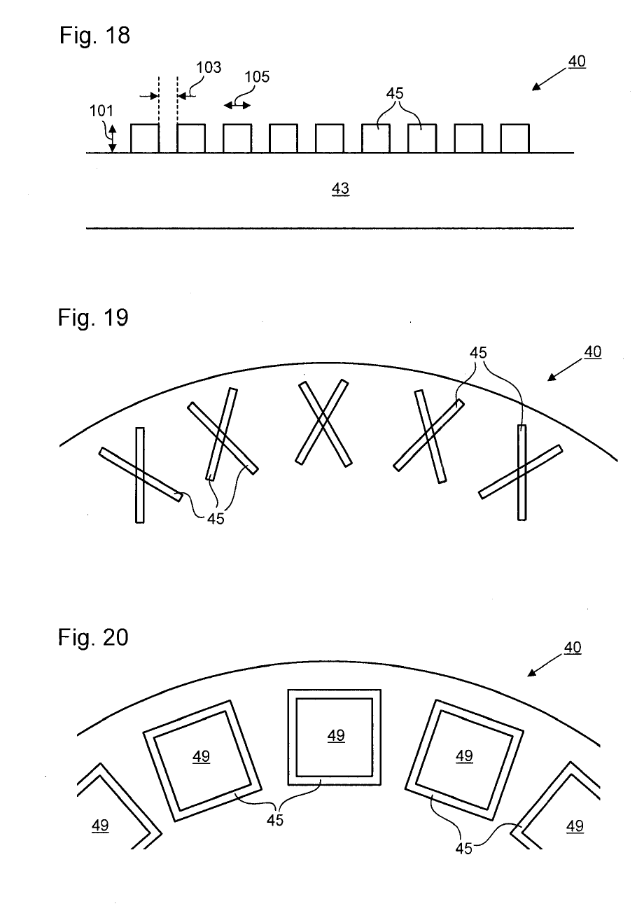

FIGS. 17 and 18 depict an example embodiment in which the cleaning substrate 40 comprises radially aligned ridges 45 on an upper surface. FIG. 17 is a schematic top view and FIG. 18 is a radially inward view. In this example, the ridges 45 do not form closed paths. Nevertheless, contaminant particles may fall into a valley between the ridges 45 and be efficiently removed from the cover 35. The particles may be particularly efficiently removed if the ridges 45 are scraped over or under the cover 35 in a direction perpendicular to the ridges 45. Such perpendicular motion can be achieved for example by rotating the substrate 40 about its axis while the ridges 45 are in contact with the cover 35. The figure is not to scale. The structures may have sizes in the sub-micron to micron range. The ridges 45 may have lengths or be separated by distances that are similar or slightly larger than the expected sizes of contaminant particles. The lengths or separation distances may be about 2 microns for example.

The ratio of the height 101 to the width 105 of the ridges may be in the range of 2:1 to 1:2 for example. Either or both of the height 101 and width 105 may be greater than the separation 103 between adjacent ridges 45.

In an embodiment, the ridges may be provided at an oblique angle relative to the radial direction. A plurality of such ridges may be provided in which all or a subset of the ridges are at the same oblique angle to the radial direction. In other embodiments, a plurality of ridges may be provided at different angles to the radial direction. For example, an arrangement may be provided in which every other ridge is at a first angle relative to the radial direction and the intervening ridges are all at a second angle, different from the first angle. Either or both of the first and second angles may be oblique. The first and second angles may be opposite in sign or the same sign. In an embodiment, the ridges are provided at the same radial position, spaced apart peripherally (e.g., circumferentially). The peripheral spacing may be the same for all ridges or may vary. The peripheral spacing between neighboring ridges and the angle may be chosen so that two or more of the ridges overlap in the radial direction. In an embodiment, two or more of the ridges may be arranged so that they do not intersect with any other ridge. In other embodiments, two or more of the ridges may be arranged to intersect. FIG. 19, discussed below, shows an example of an embodiment comprising intersecting ridges. In embodiments having one or more non-radially aligned ridges, vertical motion of the cover relative to the cleaning substrate, without rotation motion, may be sufficient to achieve a significant degree of cleaning.

FIG. 19 is a top view illustrating an example embodiment of substrate 40 comprising a plurality of structures formed by intersecting ridges 45. The figure is not to scale. The structures may have sizes in the sub-micron to micron range. The structures may have sizes that are similar or slightly larger than the expected sizes of contaminant particles. The structures may have widths or lengths of about 2 microns for example. As in the example of FIGS. 17 and 18, particles scraped off the cover 35 by the ridges 45 may fall into the regions adjacent to the ridges 45 and be removed, or carried away, from the cover 35 by the movement of the ridges 45. The particles may be particularly effectively removed where the direction of scraping has a component that is substantially perpendicular to the ridges 45. The fact that the structures comprise elements that are not aligned purely with the radial direction or peripheral (e.g., circumferential) direction in this embodiment means the structures will be effective for removing particles for a wider range of scrape directions than structures formed from linear elements aligned along the radial direction or along the peripheral direction. In the example shown; particles can be effectively removed by the ridges 45 both by peripheral scraping (e.g. movement by rotation of the cover 35 and/or substrate 40 about its axis) and by radial scraping (e.g. movement by radial and/or vertical motion of the cover 35 and/or substrate 40).

In an embodiment a plurality of structures comprising pillars may be provided. The pillars may have various cross-sectional shapes, for example circular, polygonal, or irregular shapes. The pillars may protrude in a direction perpendicular to the plane of the cleaning substrate.

FIG. 20 illustrates an example embodiment in which the ridges 45 form a plurality of enclosed regions 49. Each enclosed region 49 may be defined by a ridge 45 that forms a closed or partially closed path surrounding the enclosed region 49. One or more of these closed or partially closed paths may be positioned so as not to surround the axis of the cleaning substrate 40. For example, the enclosed regions 49 may be positioned around the peripheral edge of the cleaning substrate 40. In the example shown, none of the closed paths surrounds the cleaning substrate 40 axis, but this is not essential. In other embodiments, one or more enclosed regions defined by closed paths that surround the axis (such as the enclosed region 49 of FIG. 16) may be provided along with one or more enclosed regions defined by closed paths that do not surround the axis.

As in the enclosed region 49 of FIGS. 15 and 16, each of the enclosed regions 49 provides a region of the substrate 40 surface into which contaminants scraped off the cover 35 may fall. Such contaminants may fall and be efficiently removed from the surface of the cover 35. Ridges 45 forming closed paths that do not surround the cleaning substrate 40 axis have portions aligned both peripherally (e.g., circumferentially) and radially. The peripherally aligned portions may be more effective when the relative motion between the cleaning substrate 40 and the cover 35 is in a radial direction. The radially aligned portions of the ridges 45 may be more effective when the relative motion between the cleaning substrate and cover 35 is in a peripheral direction.

In the embodiments of FIGS. 15 to 20 the described structure is provided on the base layer 43 by use of a ridge 45. The protruding nature of the ridge 45 will tend to facilitate abrasion against the cover 35. However, a structure can be formed on the base layer 43 in other ways. For example, one or more indentations may be made in the base layer 43. The one or more indentations may be formed by etching for example. One or more indentations may form an enclosed region to receive contaminants scraped off the cover 35 for example.

In an embodiment, the cleaning substrate 40 is a plain silicon wafer (without added structure or a coating). Such a cleaning substrate 40 may be described as a cleaning substrate comprising only a base layer 43. In other embodiments, the cleaning substrate 40 may comprise only a base layer 43 with the base layer formed from a material different from silicon.

The base layer 43 in any of the embodiments discussed above may be formed from silicon, a ceramic material, a porous material, a porous ceramic material, or another material. The film 42 may comprise a porous ceramic material for example. The film 42 may be formed with organic or inorganic material. The film 42 may be formed from polymer material. The film 42 may be formed by removal (etching) through a mask or by deposition of a layer through a mask.

In an embodiment, the cleaning substrate 40 comprises a base layer 43 that has been treated to form a structure on at least one of the major faces of the base layer 43. The structure may be configured to enhance the abrasive qualities of the cleaning substrate 40. Additionally or alternatively, the structure may assist with transportation of contaminants away from the cover 35, for example by means of one or more enclosed regions or one or more other regions adjacent to ridges. Example structures have been discussed above with reference to FIGS. 12 and 15 to 20. These and other structures may desirably be provided with a characteristic length-scale of less than 2 microns. Structures of such characteristic length-scale are particularly effective for removing many types of contaminants typically present in the region of a cover 35 in a lithography apparatus. Typical contaminant particles have sizes that are less than 2 microns.

The structures discussed above, e.g. ridges, pillars, enclosed regions, or absrasive, porous or adhesive films, may be formed either on a planar region of the cleaning substrate or on the rounded or beveled edges of the cleaning substrate, or both.

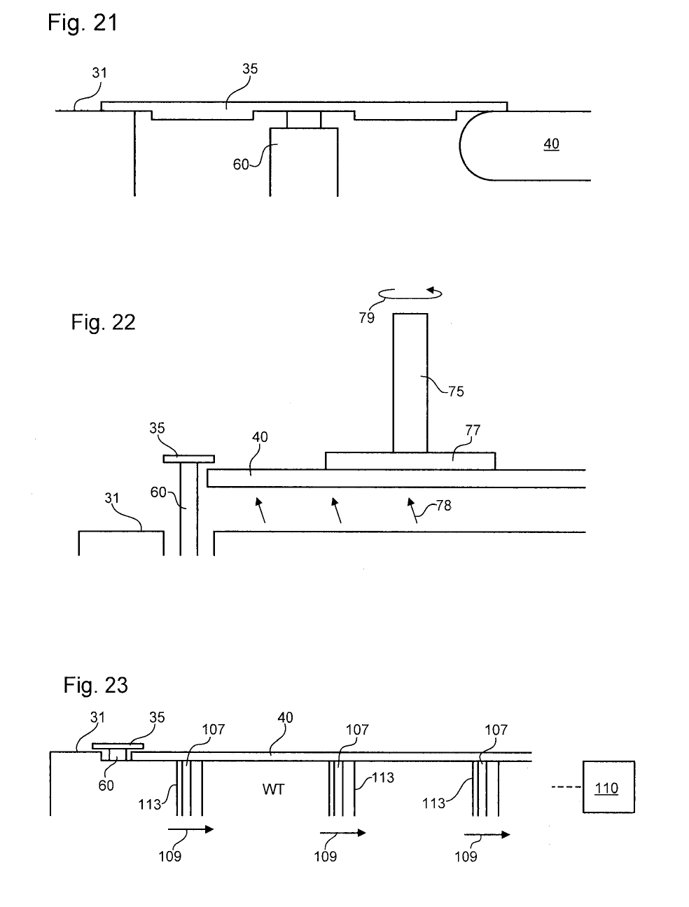

Relative movement between the cover 35 and the cleaning substrate 40 may be provided by means of a cover actuator 60. Such an actuator is described in U.S. Patent Application Publication No. US 2011-0013169, U.S. Patent Application Publication No. US 2011-0228248, and U.S. Patent Application Publication No. US 2011-0228238, each hereby incorporated by reference in its entirety. FIG. 21 is a schematic radial sectional view of the cover 35. The Figure shows a cover actuator 60 beneath the cover 35. The cover actuator 60 may be configured to move the cover vertically relative to the upper surface 31 of the substrate table WT. Alternatively or additionally, the cover actuator 60 may be configured to move the cover 35 radially and/or peripherally (e.g., circumferentially) relative to the upper surface 31 of the substrate table WT. One or more of these movement modes may be used to displace the cover 35 during changeover of a production substrate. An existing cover actuator may therefore be used with minimal or without modification for relative motion between a cover 35 and a cleaning substrate 40.

Alternatively or additionally, relative motion between the cleaning substrate 40 and the cover 35 may be provided by an abrasive member actuation system 75. In the example arrangement shown in FIG. 22, the abrasive member actuation system 75 comprises a link member 77 to hold the cleaning substrate 40. The link member 77 may comprise a suction apparatus, for example. The abrasive member actuation system 75 is configured to be able to move the cleaning substrate 40 in a vertical direction and/or in a radial direction. Alternatively or additionally, the abrasive member actuation system 75 may be configured to rotate the cleaning substrate so as to provide relative peripheral (e.g., circumferential) motion. Arrows 78 show schematically a radially outward and an upward movement of the substrate 40 towards the underside of a cover 35 that has been positioned in a raised state by the cover actuator 60. Arrow 79 illustrates rotation of the substrate 40 by actuator 75.

Alternatively or additionally, the abrasive member actuation system 75 may be configured to hold the cleaning substrate 40 stationary while the cover actuator 60 moves the cover 35 to provide the desired relative motion.

Alternatively or additionally, other apparatus may be used to hold the cleaning substrate 40 stationary while the cover 35 is moved, or vice versa.

FIG. 23 depicts an example embodiment in which the cleaning substrate 40 is held by support pins 107. In this example, the cover 35 is moved by moving a portion of the substrate table WT on which the cover 35 or cover actuator 60 is supported using a substrate table positioner 110. Possible relative movement is indicated by arrows 109. The relative motion causes the support pins 107 to move to one side of the access holes 113 within which the support pins 107 are provided. Support pins 107 may be provided to facilitate mounting and/or unmounting of a substrate into the recess 32 for example. Before moving the substrate 40 horizontally the pins 107 raise the substrate 40 from contacting the surface on the underside of the recess 32. No or minimal modifications to existing hardware therefore need to be made to support the cleaning substrate in this way. An actuator to move the portion of the substrate table on which the cover 35 or cover actuator 60 is mounted (e.g. a short-stroke module) may also be provided in existing hardware for scanning the substrate relative to the projection system. An actuator to move the table on which the support pins 107 are mounted (e.g. a long-stroke module) may also be provided in existing hardware for scanning the substrate relative to the projection system. No or minimal modifications to existing hardware may therefore need to be made to provide relative movement in this manner. In an embodiment, a reciprocating linear or rotational movement (e.g. a “wobble” movement) may be provided to the cover 35 or to substrate 40 (via the mounting pins 107). The amplitude of the movement may be chosen so that the support pins 107 will not come into contact with the walls of the access holes 113.

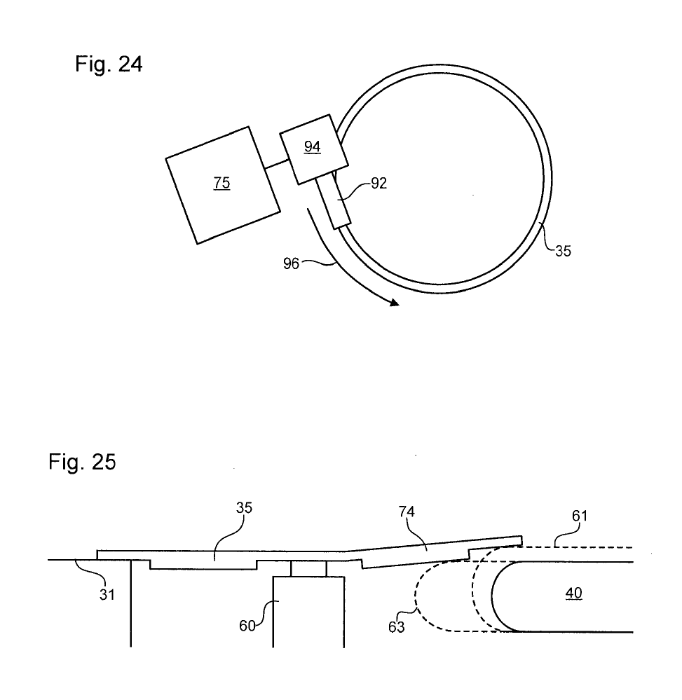

FIG. 24 depicts an example arrangement in which the abrasive member actuation system 75 is configured to drive movement of an abrasive member that is not a cleaning substrate having a form which is the same as or similar to a production substrate. In the example shown, the abrasive member 92 comprises a scalpel held by a scalpel holder 94. In an embodiment, the scalpel is a thin flexible blade. The scalpel may bend easily while applying a significant force to the cover 35. The scalpel can thus conform well to the shape of the cover 35. The scalpel may be particularly effective for removing contaminant particles that are strongly embedded in the cover 35 or secured or attached to the cover 35. In other embodiments, the abrasive member may be configured differently. For example, the abrasive member could comprise an abrasive stone (formed from a porous ceramic material for example). The abrasive stone could be similar to the abrasive stone that is used to remove resist and/or top coat from the substrate table WT for example. In an embodiment, the abrasive member comprises a brush. The abrasive member actuation system 75 in this embodiment is configured to drive the abrasive member 92 to move in a circular path 96. The circular path 96 may follow the annular form of the cover 35. In an embodiment, the abrasive member 92 is brought into contact with a lower side of the cover 35. Alternatively or additionally, the abrasive member 92 may be brought into contact with an upper surface of the cover 35. In the above described embodiments, the abrasive member is moved using an automated system. In an embodiment, the abrasive member may be used manually. In an embodiment, the abrasive member 92 is accompanied by a vacuum system to remove material that the abrasive member 92 dislodges from the cover 35. The vacuum system could be used to clean, or assist with cleaning, either or both of the top and bottom sides of the cover 35.

Any one or more of the cleaning substrates, abrasive members, and actuators described above may be considered as example components of a cover cleaning system to clean the cover 35 without removing the cover 35 from the lithography apparatus (i.e. an in-line cleaning system).

In an embodiment, the cover 35 is configured to present in use an upper surface that is substantially co-planar with the upper surface 31 of the substrate table WT surrounding the recess 32. The upper surface of the cover 35 may also be co-planar with the upper surface of the production substrate located in the recess 32 (to within a tolerance equal to about the width of the cover 35 at the edge of the cover 35). An example of such a configuration is illustrated in FIG. 21 where the cleaning substrate 40 has dimensions that are substantially identical to a production substrate for the lithography apparatus.

FIG. 25 illustrates an embodiment in which the cleaning substrate 40 is larger than a production substrate such that when the cleaning substrate 40 is located in the recess 32 it acts to push an inner peripheral edge of the cover 35 upwards when the cover 35 is in a lowermost position. Element 74 of the cover 35 in FIG. 25 represents the distortion or displacement of the cover 35 schematically. The larger cleaning substrate 40 thus prevents the cover 45 from being co-planar with the upper surface 31 of the substrate table WT. In an embodiment, the cleaning substrate 40 is radially larger than a production substrate (outline 63). In an embodiment, the cleaning substrate 40 is thicker than a production substrate (outline 61). In an embodiment, the cleaning substrate is both radially larger and thicker than a production substrate.

In an embodiment, the cleaning substrate has a width (e.g., diameter) that is larger than that of a production substrate for the lithography apparatus in which the cleaning substrate is to be used by between a lower width bound and an upper width bound. In an embodiment, the lower width bound is greater than or equal to 100 microns, desirably greater than or equal to 200 microns, or desirably greater than or equal to 500 microns. In an embodiment, the upper width bound is less than or equal to 5 mm, desirably less than or equal to 4 mm, desirably less than or equal to 3 mm, or desirably less than or equal to 2 mm.

In an embodiment, the cleaning substrate has a thickness that is larger than the thickness of a production substrate for the lithography apparatus in which the cleaning substrate is to be used by between a lower thickness bound and an upper thickness bound. In an embodiment, the lower thickness bound is greater than or equal to 100 microns, desirably greater than or equal to 200 microns, or desirably greater than or equal to 300 microns. In an embodiment, the upper thickness bound is less than or equal to 1 mm, desirably less than or equal to 700 mm, or desirably less than or equal to 400 mm.

In an embodiment, the production substrate has a diameter of 300 mm. In an embodiment, the production substrate has a diameter of 450 mm.

The disturbance to the cover 35 caused by the larger cleaning substrate 40 may facilitate cleaning of the underside of the cover 35 by radial abrasion when the cover 35 comes into contact with the cleaning substrate 40 in a vertical direction. For example, scraping of the undersurface of the cover 35 achieved by relative motion between the cover 35 and substrate 40 may be achieved by vertical motion of the cover 35 relative to the substrate 40. The relative radial movement between the cover 35 and the substrate 40 may be provided by the angle in the distorted or tilted part 74 of the cover 35.

The disturbance to the cover 35 caused by the larger cleaning substrate 40 may also help to disrupt the seal between the cover 35 and the cleaning substrate 40. Disrupting the seal may assist with the provision of a flow of cleaning fluid between the cover 35 and substrate 40. Additionally or alternatively, the gap between the cover 35 and the cleaning substrate 40 may be such as to allow access to radiation which may be used to clean the underside of the cover 35. The use of a cleaning fluid to clean the cover 35 is described further below. The use of radiation to clean the cover 35 is discussed further below.

In an embodiment, the cover 35 is brought into contact with the same cleaning substrate 40 a plurality of times. For example, the cover 35 may be brought into contact with the cleaning substrate 40 vertically and removed from the cleaning substrate 40 vertically a plurality of times. The cover 35 may also be brought into contact with the same cleaning substrate 40 a plurality of times in any direction or combination of directions.

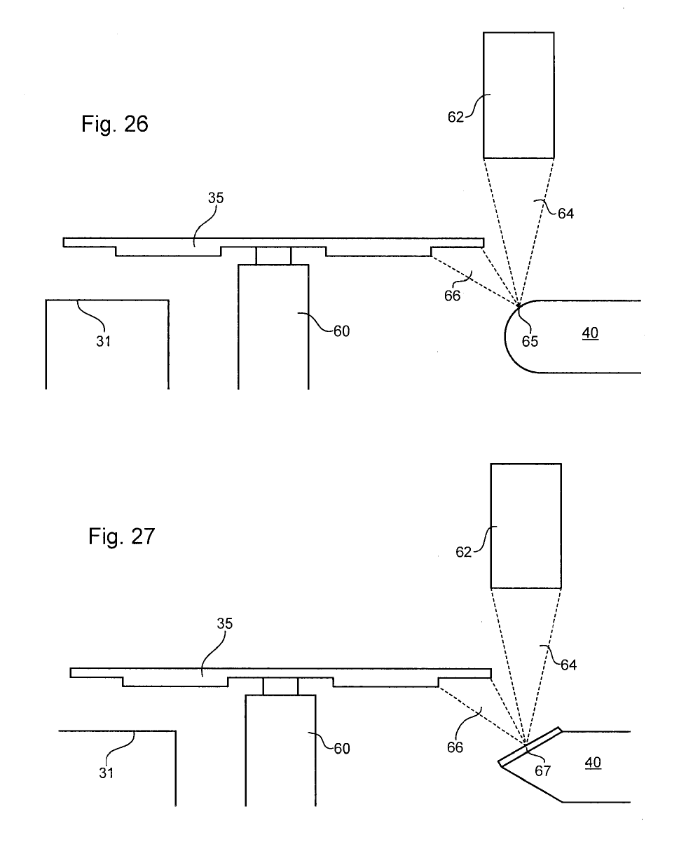

FIG. 26 illustrates an embodiment in which the cover cleaning system comprises a radiation outlet 62, for example of laser radiation such as a laser, configured to direct radiation onto the cover 35. In the example shown, the radiation 64 output from the outlet 62 is incident on to a region 65 of a cleaning substrate 40. A redirected (e.g. reflected) beam 66 is directed from the region 65 onto the underside of the cover 35. In an embodiment, the radiation 64, 66 is UV radiation. In an embodiment, the radiation is provided by the same source that is used to perform lithography on a production substrate. Alternatively or additionally, the radiation may be provided by a separate source. In an embodiment, the radiation is used in combination with ozone gas. In an embodiment, the radiation is used in combination with a material that dissociates into active components that can assist cleaning, in the presence of suitable radiation. The radiation may be laser generated radiation for example. The material may be in the form of a wafer, for example. In an embodiment, the radiation is provided by an excimer laser. In an embodiment, the radiation has a wavelength of 193 nm. The radiation may be provided by a source that is internal or external to the lithography apparatus. The radiation may be particularly effective for removing organic particles from the cover 35. In the embodiment shown in FIG. 26, the radiation is redirected (e.g., reflected) from a curved or tapered region 64 at the peripheral edge of the cleaning substrate 40. However, other arrangements are possible. For example, as shown in FIG. 27, a reflective coating 67 may be formed on the edge of the cleaning substrate 40 to assist with efficient reflection and/or to direct and/or shape the reflected radiation beam as required.

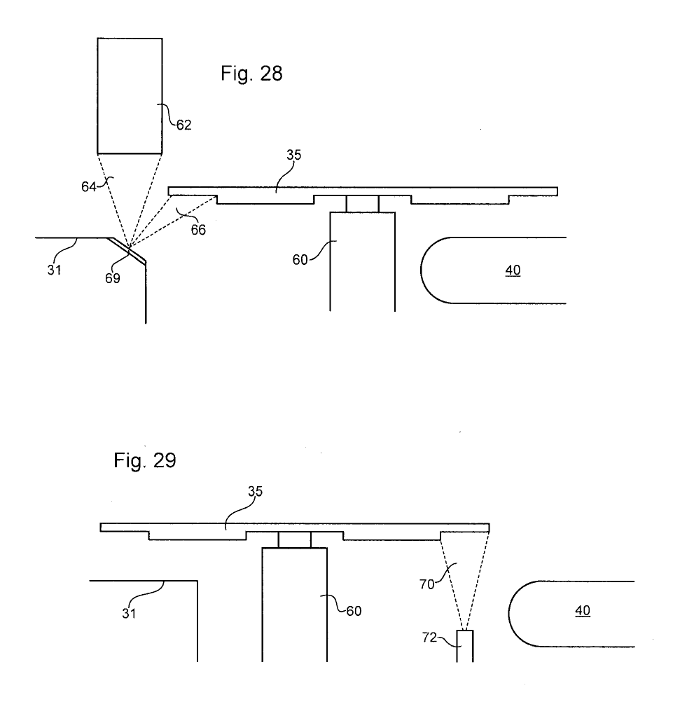

Alternatively or additionally, the radiation outlet 62 may be configured to direct radiation onto an underside of the cover 35 via redirection (e.g., reflection) from the upper surface 31 of the substrate table WT. For example, the radiation may be redirected via the upper surface 31 onto a radially outer portion of the underside of the cover 35. The radiation may be redirected directly off the upper surface 31 and/or from a reflective element 69 (as shown in FIG. 28).

Alternatively or additionally, radiation 70 may be provided directly onto the cover 35 without reflection from either the upper surface 31 of the substrate table WT or the substrate 40. For example, as shown in FIG. 29, an optical fiber 72 may be provided having an output end beneath the cover 35. The optical fiber 72 may be formed on or within the substrate 40 or the substrate table WT, for example. An end of the fiber 72 may protrude into the gap between the substrate 40 and substrate table. The end of fiber may be flush with a surface defining the gap.

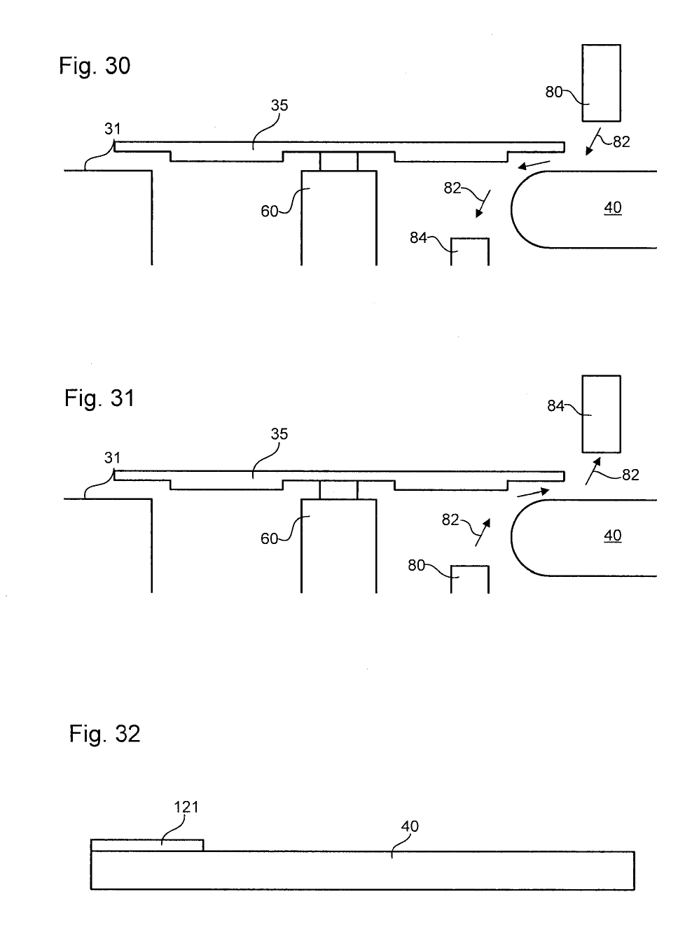

In an embodiment, a system may be provided to drive a cleaning fluid through a space between the cover 35 and a substrate 40 in the recess 32 or between the cover 35 and the upper surface 31 of the substrate table WT. Example arrangements are shown in FIGS. 30 and 31. In the example of FIG. 30, an outlet 80 (e.g., a source) outputs cleaning fluid above the cover 35 and an extractor 84 extracts fluid from beneath the cover 35. The resulting flow is illustrated schematically by arrows 82. In the example of FIG. 31, the outlet 80 is provided beneath the cover 35 and the extractor 84 is provided above the cover 35. The flow is again shown schematically by arrows 82.

The cleaning fluid may comprise ultra pure water, for example. The outlet 80 of FIG. 30 or the extractor 84 of FIG. 31 may be formed within a fluid handling structure 12 to confine an immersion fluid. The immersion fluid may be used as the cleaning fluid. The cleaning fluid may be a liquid or a gas or a mixture of liquid and gas. The cleaning fluid may be a chemical cleaning fluid. An example cleaning fluid is disclosed in U.S. Patent Application Publication No. US 2011/0080567 which is hereby incorporated by reference in its entirety.

Flushing with cleaning fluid may be used in combination with any of the above-described embodiments. For example, an abrasive cleaning step may be followed by flushing with cleaning fluid. The cleaning fluid may remove particles that have been loosened by the abrasive cleaning but not removed from the cover 35.

In an embodiment, the cover 35 may be partially or completely immersed in a liquid and subjected to ultrasonic or megasonic agitation. Alternatively or additionally, the cover 35 may be immersed partially or completely in a chemical liquid cleaning substance. For example, the cover 35 may be immersed partially or completely in a solvent, such as acetone or isopropanol, to dissolve contaminants. The solvent may be suitable for dissolving a substrate coating such as resist and/or topcoat. The use of ultrasonic or megasonic agitation and chemical liquid cleaning may normally be used offline, but could also be used in-line. Where chemical liquid cleaning is implemented in-line, this may be achieved more easily for the top surface of the cover 35 than the bottom surface.

In an embodiment, the cleaning substrate 40 may be charged relative to the cover 35. When the charged substrate 40 is brought into proximity to, or into contact with, the cover 35, contaminant particles may be pulled off the cover 35 by electrostatic forces. Alternatively or additionally, contaminant particles that are dislodged by abrasion may stick more effectively to a charged cleaning substrate 40 and be more reliably removed. FIG. 32 depicts an embodiment in which the cleaning substrate 40 comprises a charge holding member 120 to hold a charge. The charge holding member 120 may be an electrical insulator. The charge holding member 120 may have low capacitance (so that a given amount of stored charge will be associated with a relatively large voltage and thus generate a relatively strong electric field around the charge holding member 120). The charge holding member 120 may protrude slightly from the cleaning substrate as shown in FIG. 32. In other embodiments, the charge holding member 120 may be integrated into the substrate 40 so that the top of the substrate is planar.

Any of the above described methods of cleaning the cover 35 may be implemented while the cover is located within the lithography system. The cover may be positioned adjacent to the recess of the substrate table, for example, during cleaning. The cover may be in contact with a cleaning substrate located within the recess during cleaning, for example, or within a small distance of the cleaning substrate, for example within 1 cm of the cleaning substrate. The methods may be implemented as an inline cleaning operation. In other embodiments, the cleaning may be carried out offline, with the cover moved outside of the lithography apparatus.

In an embodiment, there is provided a cleaning substrate for a lithography apparatus, comprising: a base layer having a width of 300 mm or 450 mm, to within a tolerance of 2%, and a maximum thickness of less than 2 mm; and an adhesive, abrasive or porous film formed on at least one of the major faces of the base layer, the film present within 0.5 mm of the peripheral edge of the base layer.

In an embodiment, any rounding or bevelling at the edge of the major face is confined to within 0.5 mm of the peripheral edge of the base layer. In an embodiment, the film comprises one or more selected from the following: hexamethyldisilazane (HDMS), colloidal particles, sol-gel particles, a ceramic porous material, and/or a polymer porous material. In an embodiment, the cleaning substrate has a width that is larger than 300 mm or 450 mm by between 100 microns and 5 mm. In an embodiment, the cleaning substrate is thicker than 775 microns or 925 microns by between 100 microns and 1 mm. In an embodiment, width is a diameter.

In an embodiment, there is provided a cleaning method for a lithography apparatus, wherein the lithography apparatus comprises: a table having an upper surface and a recess in the upper surface that is configured to receive and support an object; a fluid handling structure configured to supply and confine immersion fluid to a space adjacent to the upper surface of the table and/or an object located in the recess; and a cover comprising a planar body that, in use, extends around the object from the upper surface at an edge of the recess to a peripheral section of an upper major face of the object in order to cover a gap between an edge of the recess and the edge of the object, wherein the method comprises: cleaning a surface of the cover.

In an embodiment, there is provided a cleaning method for a lithography apparatus, wherein the lithography apparatus comprises: a table having an upper surface and a recess in the upper surface that is configured to receive and support an object; a fluid handling structure configured to supply and confine immersion fluid to a space adjacent to the upper surface of the table and/or an object located in the recess; and a cover comprising a planar body that, in use, extends around the object from the upper surface at an edge of the recess to a peripheral section of an upper major face of the object in order to cover a gap between an edge of the recess and the edge of the object, wherein the method comprises: providing relative movement between the cover and a cleaning substrate located in the recess so as to bring the cover and the cleaning substrate into contact with each other and to remove the cover from contact with the cleaning substrate, so as to clean the cover.

In an embodiment, the cleaning substrate comprises a base layer having a structure formed on a surface thereof. In an embodiment, the structure comprises an enclosed region formed within the base layer or on top of the base layer. In an embodiment, the base layer is in the form of a disk and an outer edge of the enclosed region forms a partially or completely closed path surrounding the disk axis. In an embodiment, an outer edge of the enclosed region follows the edge of the cleaning substrate at a substantially constant distance therefrom. In an embodiment, the base layer is in the form of a disk and an outer edge of the enclosed region forms a partially or completely closed path that does not surround the disk axis. In an embodiment, the cleaning substrate comprises a base layer having a porous or adhesive film formed on a surface thereof. In an embodiment, the cleaning substrate is a plain silicon wafer without added structure or a coating. In an embodiment, the cover is configured to present in use an upper surface that is substantially co-planar with the upper surface of the table surrounding the recess and the upper surface of a production substrate located in the recess, to within a thickness of an inner or outer edge of the cover. In an embodiment, the cleaning substrate is radially larger than a production substrate such that when the cleaning substrate is located in the recess the inner peripheral edge of the cover is pushed upwards, when the cover is in a lowermost position, thus preventing the cover from being co-planar. In an embodiment, the cleaning substrate is thicker than a production substrate such that when the cleaning substrate is located in the recess the inner peripheral edge of the cover is pushed upwards, when the cover is in a lowermost position, thus preventing the cover from being co-planar. In an embodiment, the peripheral edge of the cover is pushed upwards to an extent that allows the underside of the cover to be cleaned by radial abrasion when the cover is brought into contact with the cleaning substrate in a direction perpendicular to the plane of the table. In an embodiment, the cover is brought into contact with the same cleaning substrate a plurality of times. In an embodiment, the cover is displaced or rotated relative to the table while in contact with the cleaning substrate. In an embodiment, the cleaning substrate is displaced or rotated relative to the table while in contact with the cover. In an embodiment, the cover is displaced relative to the cleaning substrate in a direction substantially perpendicular to the plane of the cleaning substrate while in contact with the cleaning substrate. In an embodiment, the cover is displaced relative to the cleaning substrate in a direction substantially parallel to the plane of the cleaning substrate while in contact with the cleaning substrate. In an embodiment, the cover is moved relative to the cleaning substrate at an oblique angle relative to the plane of the cleaning substrate while in contact with the cleaning substrate. In an embodiment, the cover is rotated relative to the cleaning substrate about an axis substantially perpendicular to the plane of the cleaning substrate while in contact with the cleaning substrate. In an embodiment, the method further comprises applying an electric charge to the cleaning substrate before bringing the cleaning substrate into contact with the cover. In an embodiment, the method further comprises driving a cleaning fluid through a space between the cover and an object in the recess or between the cover and the upper surface of the table in order to clean the cover. In an embodiment, the method further comprises directing radiation onto the cover in order to clean the cover. In an embodiment, the object is a radiation-sensitive substrate and the table is a substrate table.

In an embodiment, there is provided a cleaning method for a lithography apparatus, wherein the lithography apparatus comprises: a table having an upper surface and a recess in the upper surface that is configured to receive and support an object; a fluid handling structure configured to confine immersion fluid to a space adjacent to the upper surface of the table and/or an object located in the recess; and a cover comprising a planar body that, in use, extends around the object from the upper surface to a peripheral section of an upper major face of the object in order to cover a gap between an edge of the recess and an edge of the object, wherein the method comprises: directing radiation onto the cover in order to clean the cover.

In an embodiment, the radiation is directed onto the cover by reflection from a cleaning substrate located in the recess. In an embodiment, the radiation is applied to a non-planar edge of the cleaning substrate so as to be reflected towards the cover. In an embodiment, the radiation is directed onto a reflective coating formed on the edge of the cleaning substrate. In an embodiment, the radiation is directed onto the cover by reflection from the table. In an embodiment, the radiation is directed onto the cover by an optical fiber. In an embodiment, the radiation is UV radiation.

In an embodiment, there is provided a lithography apparatus comprising: a table having an upper surface and a recess in the upper surface that is configured to receive and support an object; a fluid handling structure configured to confine immersion fluid in a space adjacent to the upper surface of the table and/or an object located in the recess; a cover comprising a planar body that, in use, extends around the object from the upper surface to a peripheral section of an upper major face of the object in order to cover a gap between an edge of the recess and an edge of the object; and an abrasive member actuation system to hold an abrasive member against the cover and to provide relative movement between the abrasive member and the cover while the abrasive member contacts the cover.

In an embodiment, the abrasive member comprises a cleaning substrate as described herein. In an embodiment, the abrasive member comprises one or more selected from the following: a scalpel, a brush, and/or a porous ceramic material. In an embodiment, the abrasive member actuation system is configured to move the abrasive member relative to the table. In an embodiment, the abrasive member actuation system is configured to rotate the abrasive member relative to the table. In an embodiment, the abrasive member actuation system is configured to move the abrasive member in a circular path relative to the table while maintaining contact with the cover. In an embodiment, the abrasive member actuation system is configured to hold the abrasive member by vacuum suction.

In an embodiment, there is provided a lithography apparatus comprising: a table having an upper surface and a recess in the upper surface that is configured to receive and support an object; a fluid handling structure configured to confine immersion fluid in a space adjacent to the upper surface of the table and/or an object located in the recess; a cover comprising a planar body that, in use, extends around the object from the upper surface to a peripheral section of an upper major face of the object in order to cover a gap between an edge of the recess and an edge of the object; and a radiation outlet configured to direct radiation onto the cover.

In an embodiment, the radiation is directed onto the cover by reflection from an object in the recess or from the upper surface of the table. In an embodiment, the radiation is directed onto a reflective coating formed on the edge of the object or on the edge of the upper surface of the table. In an embodiment, the lithography apparatus further comprises an optical fiber to direct the radiation onto the cover. In an embodiment, the optical fiber is formed on or within an object in the recess, the table, or both. In an embodiment, the lithography apparatus further comprises: a projection system configured to project a patterned radiation beam onto a target portion of a substrate, wherein: the lithography apparatus is configured to use a radiation beam output from the projection system as the radiation to clean the cover.

In an embodiment, there is provided a lithography apparatus comprising: a table having an upper surface and a recess in the upper surface that is configured to receive and support an object; a fluid handling structure configured to confine immersion fluid in a space adjacent to the upper surface of the table and/or an object located in the recess; a cover comprising a planar body that, in use, extends around the object from the upper surface to a peripheral section of an upper major face of the object in order to cover a gap between an edge of the recess and an edge of the object; and a cover cleaning system to clean a surface of the cover.

In an embodiment, the cover cleaning system comprises a cleaning fluid outlet and an extractor to drive a cleaning fluid through a space between the cover and an object in the recess or between the cover and the upper surface of the table in order to clean the cover. In an embodiment, the cleaning fluid outlet is above the cover and the extractor is below the cover. In an embodiment, the cleaning fluid outlet is below the cover and the extractor is above the cover. In an embodiment, the cleaning fluid comprises one or more selected from the following: immersion fluid, ultra pure water, a liquid, and/or a gas. In an embodiment, the lithography apparatus further comprises a cover actuation system to displace or rotate the cover relative to the table in order to provide the space between the space between the cover and the object and/or the space between the cover and the upper surface of the table. In an embodiment, the lithography apparatus further comprises a cleaning substrate that when provided in the recess has an upper surface that is higher than the upper surface of the table so as to prevent sealing of the cover against the cleaning substrate.

As will be appreciated, any of the above described features can be used with any other feature and it is not only those combinations explicitly described which are covered in this application. For example, an embodiment of the invention could be applied to the embodiments of FIGS. 2 to 6. Further, while the description has focused on a cover for a production substrate on a substrate table, the cover may be for a different object on the substrate table or other table. For example, the object may be a sensor.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The terms “radiation” and “beam” used herein encompass all types of electromagnetic radiation, including ultraviolet (UV) radiation (e.g. having a wavelength of or about 365, 248, 193, 157 or 126 nm). The term “lens”, where the context allows, may refer to any one or combination of various types of optical components, including refractive and reflective optical components.

While specific embodiments of the invention have been described above, it will be appreciated that the invention may be practiced otherwise than as described. For example, the embodiments of the invention may take the form of a computer program containing one or more sequences of machine-readable instructions describing a method as disclosed above, or a data storage medium (e.g. semiconductor memory, magnetic or optical disk) having such a computer program stored therein. Further, the machine readable instruction may be embodied in two or more computer programs. The two or more computer programs may be stored on one or more different memories and/or data storage media.

Any controllers described herein may each or in combination be operable when the one or more computer programs are read by one or more computer processors located within at least one component of the lithographic apparatus. The controllers may each or in combination have any suitable configuration for receiving, processing, and sending signals. One or more processors are configured to communicate with the at least one of the controllers. For example, each controller may include one or more processors for executing the computer programs that include machine-readable instructions for the methods described above. The controllers may include data storage medium for storing such computer programs, and/or hardware to receive such medium. So the controller(s) may operate according the machine readable instructions of one or more computer programs.

One or more embodiments of the invention may be applied to any immersion lithography apparatus, in particular, but not exclusively, those types mentioned above and whether the immersion liquid is provided in the form of a bath, only on a localized surface area of the substrate, or is unconfined. In an unconfined arrangement, the immersion liquid may flow over the surface of the substrate and/or substrate table so that substantially the entire uncovered surface of the substrate table and/or substrate is wetted. In such an unconfined immersion system, the liquid supply system may not confine the immersion liquid or it may provide a proportion of immersion liquid confinement, but not substantially complete confinement of the immersion liquid.

A liquid supply system as contemplated herein should be broadly construed. In certain embodiments, it may be a mechanism or combination of structures that provides a liquid to a space between the projection system and the substrate and/or substrate table. It may comprise a combination of one or more structures, one or more fluid openings including one or more liquid openings, one or more gas openings or one or more openings for two phase flow. The openings may each be an inlet into the immersion space (or an outlet from a fluid handling structure) or an outlet out of the immersion space (or an inlet into the fluid handling structure). In an embodiment, a surface of the space may be a portion of the substrate and/or substrate table, or a surface of the space may completely cover a surface of the substrate and/or substrate table, or the space may envelop the substrate and/or substrate table. The liquid supply system may optionally further include one or more elements to control the position, quantity, quality, shape, flow rate or any other features of the liquid.

The descriptions above are intended to be illustrative, not limiting. Thus, it will be apparent to one skilled in the art that modifications may be made to the invention as described without departing from the scope of the claims set out below.

1. A cleaning method for a lithography apparatus, wherein the lithography apparatus comprises:
a table having an upper surface and a recess in the upper surface that is configured to receive and support an object;
a fluid handling structure configured to supply and confine immersion fluid to a space adjacent to the upper surface of the table and/or an object located in the recess; and
a cover comprising a planar body that, in use, extends around the object from the upper surface at an edge of the recess to a peripheral section of an upper major face of the object in order to cover a gap between an edge of the recess and the edge of the object, wherein the method comprises:
cleaning a surface of the cover.

2. The method according to claim 1, wherein the cleaning substrate comprises a base layer having a structure formed on a surface thereof.

3. The method according to claim 2, wherein the structure comprises an enclosed region formed within the base layer or on top of the base layer, and the base layer is in the form of a disk and an outer edge of the enclosed region forms a partially or completely closed path surrounding the disk axis.

4. The method according to claim 3, wherein an outer edge of the enclosed region follows the edge of the cleaning substrate at a substantially constant distance therefrom.

5. The method according to claim 1, wherein the cleaning substrate comprises a base layer having a porous or adhesive film formed on a surface thereof.

6. The method according to claim 1, wherein the cleaning substrate is a plain silicon wafer without added structure or a coating.

7. The method according to claim 1, wherein the cover is configured to present in use an upper surface that is substantially co-planar with the upper surface of the table surrounding the recess and the upper surface of a production substrate located in the recess, to within a thickness of an inner or outer edge of the cover.

8. The method according to claim 7, wherein the cleaning substrate is thicker than a production substrate such that when the cleaning substrate is located in the recess the inner peripheral edge of the cover is pushed upwards, when the cover is in a lowermost position, thus preventing the cover from being co-planar.

9. The method according to claim 7, wherein the cleaning substrate is radially larger than a production substrate such that when the cleaning substrate is located in the recess the inner peripheral edge of the cover is pushed upwards, when the cover is in a lowermost position, thus preventing the cover from being co-planar.

10. The method according to claim 9, wherein the peripheral edge of the cover is pushed upwards to an extent that allows the underside of the cover to be cleaned by radial abrasion when the cover is brought into contact with the cleaning substrate in a direction perpendicular to the plane of the table.

11. The method according to claim 1, wherein the cleaning substrate comprises:
a base layer having a width of 300 mm or 450 mm, to within a tolerance of 2%, and a maximum thickness of less than 2 mm; and
an adhesive, abrasive or porous film formed on at least one of the major faces of the base layer, the film present within 0.5 mm of the peripheral edge of the base layer.

12. The method according to claim 1, wherein the cleaning substrate is displaced or rotated relative to the table while in contact with the cover.

13. The method according to claim 1, wherein the cover is displaced relative to the cleaning substrate in a direction substantially perpendicular and/or substantially parallel to the plane of the cleaning substrate while in contact with the cleaning substrate.

14. The method according claim 1, further comprising applying an electric charge to the cleaning substrate before bringing the cleaning substrate into contact with the cover.

15. The method according to claim 1, further comprising driving a cleaning fluid through a space between the cover and an object in the recess or between the cover and the upper surface of the table in order to clean the cover.

16. The method according to claim 1, further comprising directing radiation onto the cover in order to clean the cover.

17. A cleaning method for a lithography apparatus, wherein the lithography apparatus comprises:
a table having an upper surface and a recess in the upper surface that is configured to receive and support an object;
a fluid handling structure configured to supply and confine immersion fluid to a space adjacent to the upper surface of the table and/or an object located in the recess; and
a cover comprising a planar body that, in use, extends around the object from the upper surface at an edge of the recess to a peripheral section of an upper major face of the object in order to cover a gap between an edge of the recess and the edge of the object, wherein the method comprises:
providing relative movement between the cover and a cleaning substrate located in the recess so as to bring the cover and the cleaning substrate into contact with each other and to remove the cover from contact with the cleaning substrate, so as to clean the cover.

18. A cleaning substrate for a lithography apparatus, comprising:
a base layer having a width of 300 mm or 450 mm, to within a tolerance of 2%, and a maximum thickness of less than 2 mm; and
an adhesive, abrasive or porous film formed on at least one of the major faces of the base layer, the film present within 0.5 mm of the peripheral edge of the base layer.

19. A cleaning method for a lithography apparatus, wherein the lithography apparatus comprises:
a table having an upper surface and a recess in the upper surface that is configured to receive and support an object;
a fluid handling structure configured to confine immersion fluid to a space adjacent to the upper surface of the table and/or an object located in the recess; and
a cover comprising a planar body that, in use, extends around the object from the upper surface to a peripheral section of an upper major face of the object in order to cover a gap between an edge of the recess and an edge of the object, wherein the method comprises:
directing radiation onto the cover in order to clean the cover.

20. A lithography apparatus comprising:
a table having an upper surface and a recess in the upper surface that is configured to receive and support an object;
a fluid handling structure configured to confine immersion fluid in a space adjacent to the upper surface of the table and/or an object located in the recess;
a cover comprising a planar body that, in use, extends around the object from the upper surface to a peripheral section of an upper major face of the object in order to cover a gap between an edge of the recess and an edge of the object; and
a cover cleaning system to clean a surface of the cover.
